(19) United States
(12) Patent Application Publication
(10) Pub. No.: US 2026/0118922 A1
(43) Pub. Date: Apr. 30, 2026

(54) INFORMATION HANDLING SYSTEM AIR FILTER

(71) Applicant: Dell Products L.P., Round Rock, TX (US)

(72) Inventors: Derric C. Hobbs, Round Rock, TX (US); Jason T. Minehart, Cedar Park, TX (US); Timothy R. Graham, Georgetown, TX (US)

(73) Assignee: Dell Products L.P., Round Rock, TX (US)

(21) Appl. No.: 18/930,148

(22) Filed: Oct. 29, 2024

(51) Int. Cl. G06F 1/18; G06F 1/20; H05K 5/02; H05K 5/06

(52) U.S. Cl. CPC G06F 1/182; G06F 1/20; H05K 5/0221; H05K 5/061; G06F 2200/201

(57) ABSTRACT

An information handling system housing has a first air filter slot at a rear top side and a second air filter slot at a rear bottom side, each of the air filter slots accepting an air filter having a conductive wire mesh overmolded in a plastic frame and interfaced with a housing ground by a conductive gasket on the air filter perimeter. The grounded conductive mesh filters air through top and bottom openings of the housing having a perimeter of the housing for maximal airflow that is sealed by the conductive gasket for improved EMI and acoustics.

### BACKGROUND OF THE INVENTION

### Field of the Invention

The present invention relates in general to the field of information handling systems, and more particularly to an information handling system air filter.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems include processing components in a housing that cooperate to process information. Desktop and tower configurations generally assemble the components into a housing that operates from a fixed location and interacts with an end user through peripheral devices, such as peripheral displays, a peripheral keyboard, a peripheral mouse, external speakers, headsets and goggles. Information handling systems that operate from a fixed location typically support more powerful and expensive processing components to more quickly accomplishing processing tasks, such as gaming. For example, a tower or desktop housing tends to have an increased amount of space within the housing interior to mount processing components having an increased footprint and also to include cooling equipment that removes excess thermal energy dissipated as heat when the processing components use power. Thermal management can include multiple high capacity cooling fans and water cooling systems. Often, high end gaming information handling systems include specialized equipment and arrangements to maintain a central processing unit (CPU) and a graphics processing unit (GPU) within operational temperature constraints.

In high end gaming, end users often specialize their own information handling systems with hardware modifications that enhance performance. The modifications can include enhanced processors, high speed memory and storage, high speed graphics cards, high capacity cooling fans and liquid cooling systems. Many advanced gamers will build an information handling system from scratch. Generally, in the gaming space manufacturers try to design systems to have adaptability for modifications to address the independent creativity streak of the gaming market segment. In this regard, information handling system housings should permit ready access by the end user so that components can be removed and swapped out with minimal effort. On the other hand, many of the components in gaming systems are quite expensive so that security to prevent unauthorized access is generally included with the housing. Physical security at the housing also prevents malicious attacks that involve modifications and interactions with the hardware components, such as swapping a firmware element that includes a malicious element like a keyboard tracker. When hardware changes introduce malicious elements at the system root, software security systems are often limited in their ability to detect and eradicate the malicious element.

One security solution is to have multiple access levels with different levels of security. For instance, a glass front cover might offer a visual view of the main components to allow an end user to visually inspect for operating conditions without unlocking the glass cover. A difficulty with this approach is that the glass cover has to include electromagnetic interference (EMI) shielding and sufficient physical strength to resist a break in. When an end user accesses the components through the glass door, space restrictions typically prevent full access to all of the internal components. Instead, there is typically other entrance points to the housing that allow full access to the components. For instance, the entire housing side walls will typically lift off the main chassis so that the end user can access the internal components from all directions. In some instances, an end user has to fully remove the side walls to perform even minor maintenance, such as changing air filters at the system vent intakes. When an end user wants to secure each of the entrance points to the housing, it often involves a lock and key at each entrance point. If any one entrance point is inadvertently left unlocked, the system is vulnerable to unauthorized entry.

A difficulty that can arise with information handling systems that encourage end user customization by changing internal components is that in some cases the selected components do not securely couple in the housing. Typically, electronic components include standardized connection interfaces, such as the PCIe and M.2 slot connectors, however, the component itself can fall within the standard constraints yet have variations in length, width and height that can interfere with the housing configuration. If a subset of possible components do not fit in the housing, an end user who wants to customize his system may have a poor user experience. Systems that have greater flexibility to accept different components will find wider acceptance in the market where end users appreciate the freedom to adapt a system to a desired performance level.

### SUMMARY OF THE INVENTION

Therefore, a need has arisen for a system and method which provides a single point locking mechanism to secure and release multiple housing covers.

A further need exists for a locking mechanism with a simple end user interface that secures with an external locking device.

A further need exists for a liquid cooling assembly that mounts in a housing to have ready end user access with a wide area to draw cooling airflow without leaks between the housing interior and exterior.

A further need exists for a air filter that fits the wide area of the cooling airflow while also suppressing EMI.

A further need exists for a graphics card mounting and release assembly to secure graphics cards in an information handling system housing across a variety of physical dimensions.

In accordance with the present invention, a system and method are provided which substantially reduce the disadvantages and problems associated with previous methods and systems to secure an information handling system's interior components while supporting ready modification to the components in a convenient manner. An information handling system housing has a single point locking mechanism and interrelated housing covers so that all housing covers are secured and released by the single locking mechanism.

More specifically, an information handling system housing has a motherboard coupled to an inner chassis that is covered by side, top, bottom and front covers. A locking mechanism at a rear side of the housing has a rotational member that rotates between a locked and unlocked position. In the locked position when all of the housing covers are in place, the single locking mechanism secures all of the housing covers to the inner chassis. When the locking mechanism is rotated to an unlocked position, two release buttons on the rear side actuate independently to release a transparent side cover and a non-transparent side cover. The transparent side cover has a glass substrate treated with silver, indium tin oxide and silicon dioxide to suppress EMI from crossing the transparent side cover. Once the transparent side cover is removed, a top cover may be removed to access a liquid cooling module assembly that couples in an opening at the top of the housing and uses blanks to manage different sized liquid cooling modules in an efficient airflow management. An air filter couples over the top opening and includes a conductive mesh that filters air and suppresses EMI. Within the housing a graphics card adapter moves between plural positions to adapt the housing to accept graphics cards with a variety of heights, widths and lengths. A release actuator between the graphics card and PCIe slot of the motherboard or a daughter board helps to press the graphics card out of the card slot where finger access is restricted.

The present invention provides a number of important technical advantages. One example of an important technical advantage is that an information handling system readily adapts to accept end user modifications, such as graphics card selections, with a single securing access point managed by a rotational member. An end user who opens the housing can tell from a visual inspection that all access to the housing is restricted without having separate locking devices on multiple housing covers. The transparent cover is treated with silver and indium tin oxide to suppress EMI with a clear view to the housing interior that a coat of silicon dioxide prevents from oxidation. A metal mesh air filter coupled by a conductive EMI gasket to the housing maximizes cooling airflow through the housing while managing EMI suppression and acoustics. A graphics card adapter visible through the transparent housing quickly and securely adapts to accept a wide variety of graphics card dimensions with minimal system breakdown.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts a front side perspective view of an information handling system having a housing secured with a single locking mechanism for plural side covers that access the housing interior;

FIG. 2 depicts an exploded front side perspective view of the information handling system having the side and top covers removed;

FIG. 3 depicts a rear side view of the information handling system having the release latch buttons and locking mechanism rotational member;

FIGS. 4 and 4A depict a rear side perspective view of the information handling system having removal of the transparent side cover as a single actuation;

FIGS. 5 and 5A depict a rear side perspective view of the information handling system having removal of the non-transparent side cover as a single actuation;

FIGS. 6, 6A and 6B depict rear side and sectional views of the locking mechanism with engagement of the side covers to the housing with the locking mechanism in an unlocked position;

FIGS. 7, 7A and 7B depict rear side and sectional views of the locking mechanism with engagement of the side covers to the housing with the locking mechanism in a locked position;

FIG. 8 depicts a front left exploded perspective view of a full breakdown of the housing once the lock is unlocked and the side covers are removed;

FIG. 9 depicts an upper rear perspective view of the housing top cover exploded from the housing;

FIG. 10 depicts an upper rear perspective view of the housing bottom cover exploded from the housing;

FIG. 11 depicts a front lower perspective exploded view of the front cover separated from the bottom cover;

FIG. 12 depicts a rear upper perspective exploded view of the front cover and top cover separate from the housing;

FIGS. 13, 13A and 13B depict engagement of the non-transparent solid cover with the front cover;

FIGS. 14, 14A and 14B depict engagement of the transparent side cover with the front cover;

FIGS. 15 and 15A depict front perspective and exploded views of the locking mechanism having locking pins that actuate in opposing directions;

FIG. 16 depicts the locking mechanism with the rotational member removed to illustrate engagement of the rotational member with the locking pins;

FIGS. 17A and 17B depict a front sectional view of the locking mechanism having the location of the pins in the cammed slots when the rotational member is in the locked and unlocked position;

FIGS. 18 and 18A depict an alternative embodiment of the locking mechanism in a locked position having locking pins traveling laterally motivated by a cam surface of the rotational member;

FIGS. 19 and 19A depict the locking mechanism alternative embodiment in an unlocked position;

FIG. 20 depicts a front perspective exploded view of the locking mechanism alternative embodiment with a cam on the inner side of the rotational member;

FIG. 21 depicts a rear side perspective exploded view of the information handling system having a liquid cooling assembly mounted under a housing top cover;

FIG. 22 depicts a top perspective exploded view of an example embodiment of a liquid cooling mounting frame;

FIG. 23 depicts a top perspective exploded view of another example embodiment of a liquid cooling mounting frame;

FIG. 24 depicts a top perspective exploded view of another example embodiment of a liquid cooling mounting frame;

FIG. 25 depicts an upper perspective view of one example of the mounting frame supporting a liquid cooling module with only a portion of the mounting frame surface area used;

FIG. 26 depicts an upper perspective view of another example of the mounting frame supporting a liquid cooling module with only a portion of the mounting frame surface area used;

FIGS. 27, 27A and 27B depict example embodiments of a transparent side cover assembly that provides viewing into a housing interior while preventing EMI from escaping the housing enclosure;

FIGS. 28 and 28A depict an alternative embodiment for applying a conductive layer to the transparent substrate of the transparent side cover;

FIGS. 29A, 29B, 29C and 29D depict an example embodiment of coupling of a GPU card into the information handling system housing with an add-in card (AIC) adapter;

FIG. 30 depicts a side perspective exploded view of an example embodiment of the add-in card adapter assembly;

FIG. 31 depicts an add-in card adapter aligned for insertion into slots of a coupling assembly of the system chassis;

FIG. 32 depicts a rear of the chassis at the coupling assembly having a locking bracket to hold the add-in card adapter in place when secured by the set screw;

FIG. 33 depicts an example embodiment of coupling of a graphics card by a C-shaped bracket and insertion pins that fit into the add-in card adapter;

FIGS. 34A and 34B depict an example embodiment of coupling of a graphics card by a U-shaped bracket and a straight extender bracket;

FIG. 35 depicts a rear side perspective view of air filters that slide into slots of the information handling system;

FIGS. 36A, 36B and 36C depict an example embodiment of the top filter that illustrates the integrated EMI design;

FIG. 37 depicts an exploded perspective view of the bottom filter having a construction similar to the top filter;

FIGS. 38, 38A and 38B depict an example embodiment of a PCIe slot latch release to assist removal of a graphics card coupled to a circuit board;

FIGS. 39, 39A, 39B, 39C, 39D, 39E and 39FC depict an example embodiment of a graphics card bottom support to aid in retention of a graphics card at a circuit board;

FIGS. 40, 40A and 40B depict an alternative example of a PCIe slot latch release having a release button accessible at the circuit board that accepts a press to lift a graphics card out of the PCIe slot;

FIGS. 41 and 41A depict a bottom view of the alternative example of the PCIe latch release having a wire that transfers release actuation; and

FIG. 42 depicts an exploded perspective view of the alternative example of the PCIe latch release.

### DETAILED DESCRIPTION

An information handling system housing secures at a single locking mechanism multiple housing cover access points. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

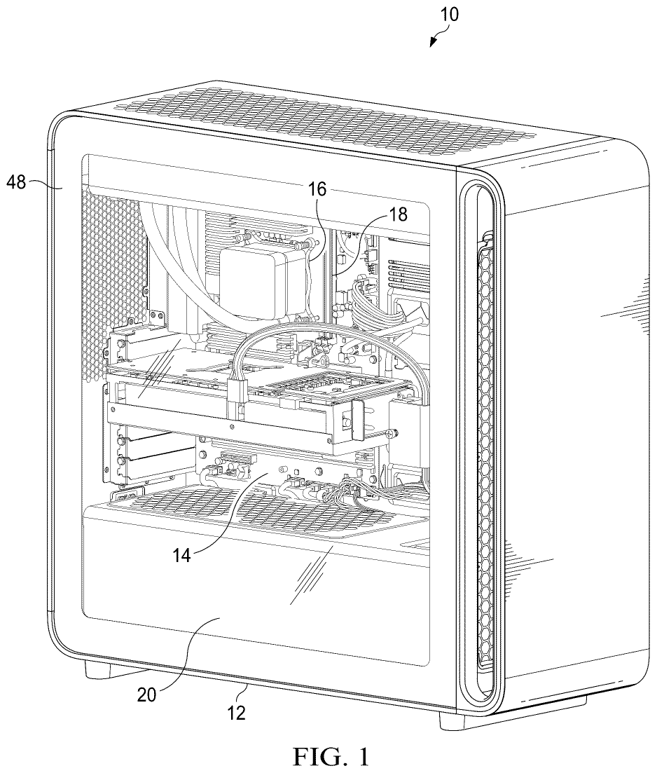

Referring now to FIG. 1, a front side perspective view depicts an information handling system 10 having a housing 12 secured with a single locking mechanism for plural side covers that access the housing interior. Information handling system 10 couples a motherboard 14 in the interior of housing 12 that interfaces a central processing unit (CPU) 16 and random access memory (RAM) 18. CPU 16 executes instructions to process information, such as instructions of an operating system and application, and interfaces with RAM 18, which stores the information and instructions for access by the CPU. Other processing components included in housing 12 interface through motherboard 14 with CPU 16 to manage system operations, such as a solid state drive (SSD) that provides persistent storage, an embedded controller that manages power and thermals, a wireless network interface controller (WNIC) that manages WIFI and Ethernet interfaces and a graphics processing unit (GPU) that manages presentation of information as visual images at a display. A transparent side panel 20 provides an end user with a view into the housing interior while the housing is closed. In the example, housing 12 has a central chassis 48 with side covers coupled to the central chassis that are removeable to provide an end user with access into the central chassis.

In the example embodiment, left and right side removeable covers each have an independent latching mechanism actuated from a rear side of housing 12. A dual locking mechanism at the housing rear engages both latches so that, when locked, pins of the locking mechanism engage the latches to prevent movement to an open position for either the left or right latch. When the locking mechanism is unlocked, each latch actuates separately so the end user can individually remove the side covers. The single locking mechanism advantageously provides a single security point for the end user to secure and release the side covers. In addition, top, front, bottom and rear rail covers interlock with one or both of the side covers so that, when the side covers are locked, the housing top, front and bottom covers are also locked. In particular, when the transparent side cover 20 is installed, none of the top, front and bottom covers may be removed. When an external lock is coupled to the locking mechanism in a locked position, an end user has assurance that the single lock protects against all access to the housing interior as long as the transparent side cover is latched into place.

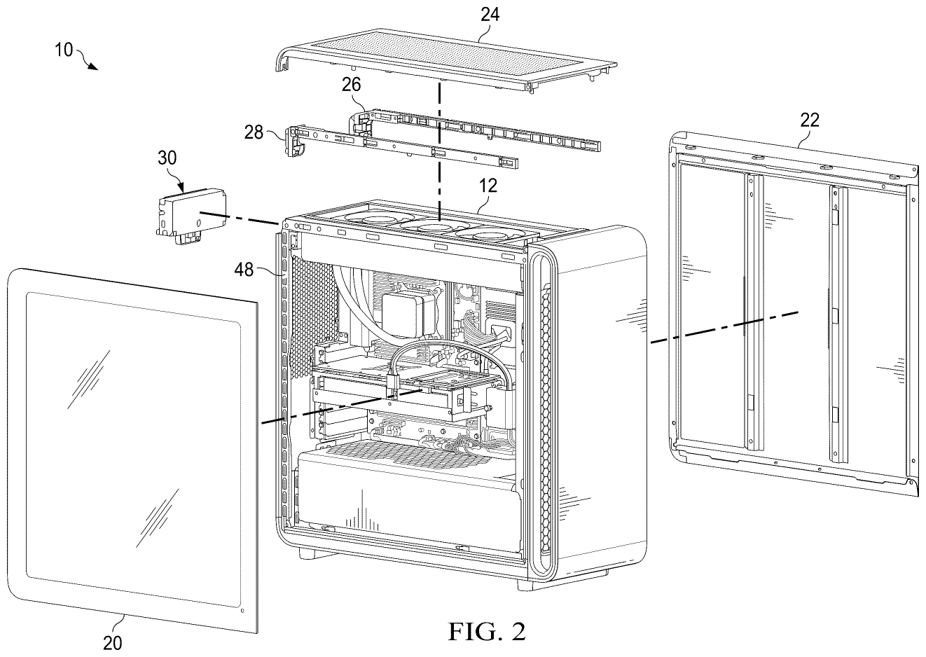

Referring now to FIG. 2, an exploded front side perspective view depicts the information handling system 10 side and top covers removed. Transparent side cover 20 couples to the left side of housing 12 and a solid non-transparent side cover 22 couples to the right side of housing 12. A left side latch 28 couples to transparent side cover 20 with a slot and hook arrangement and with the end of left side latch 28 exposed as a button at a rear side of housing 12. A right side latch 26 couples to the solid side cover 22 with the slot and hook arrangement and with the end of latch 26 exposed as a button at a rear side of housing 12. Both of latches 26 and 28 have a spring coupled between the latch and housing to bias the latch to a rearward position that extends the buttons at the terminating ends of the latches out a rear side of the housing. When a latch 26 and/or 28 is pressed forward from the button at the rear side, the slot and hook arrangements release the side covers for removal from the housing. A locking mechanism 30 moves between a locked position that prevents a press at the buttons and an unlocked position that allows a press at the buttons. Although a single lock position locks both the latches and the side covers, the separate buttons at the rear side of housing 12 support separate actuation and separate removal of the two side covers. In one alternative embodiment, the locking mechanism rotates to multiple positions so that one cover is unlocked to allow a press of the button while the other button is prevented from actuation. In the example embodiment, a top cover 24 couples to the top of housing 12 and engages transparent side cover 20 so that top cover 24 is held in position until transparent side cover 20 is removed.

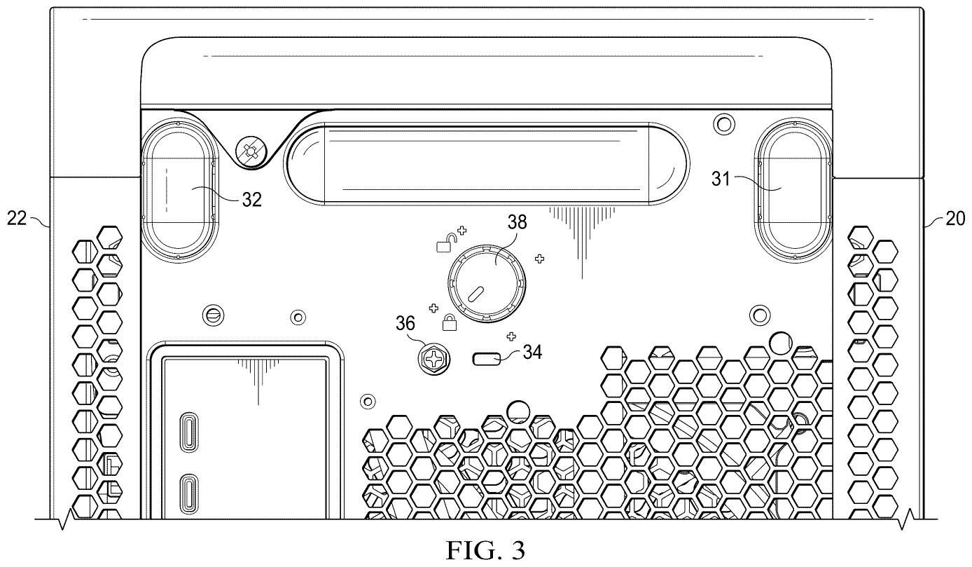

Referring now to FIG. 3, a rear side view of the information handling system depicts the release latch buttons 31 and 32 and locking mechanism rotational member 38. Rotational member 38 is a dial that rotates between a locked position shown and an unlocked position to clockwise. In the locked position, push buttons 31 and 32 are prevented from accepting a press that will release the left transparent side cover 20 and the right solid non-transparent side cover 22 latches described above. A Kennsington lock slot 34 accepts a Kennsington lock to secure rotational member 38 in the locked position and retain the information handling system by a cable to a fixed location. Other types of external locking devices may be used, such as a padlock that inserts through an opening of rotational member 38 to prevent rotation, such as a hole drilled through the dial. A safety screw 36 inserts into the locking mechanism to prevent rotation to an unlocked position, such as when 240VAC power is interfaced with the system. In one example embodiment, removal of the safety screw 36 cuts off power at the information handling system so that the system cannot be unlocked unless the safety screw is removed and power shut off by removal of the screw.

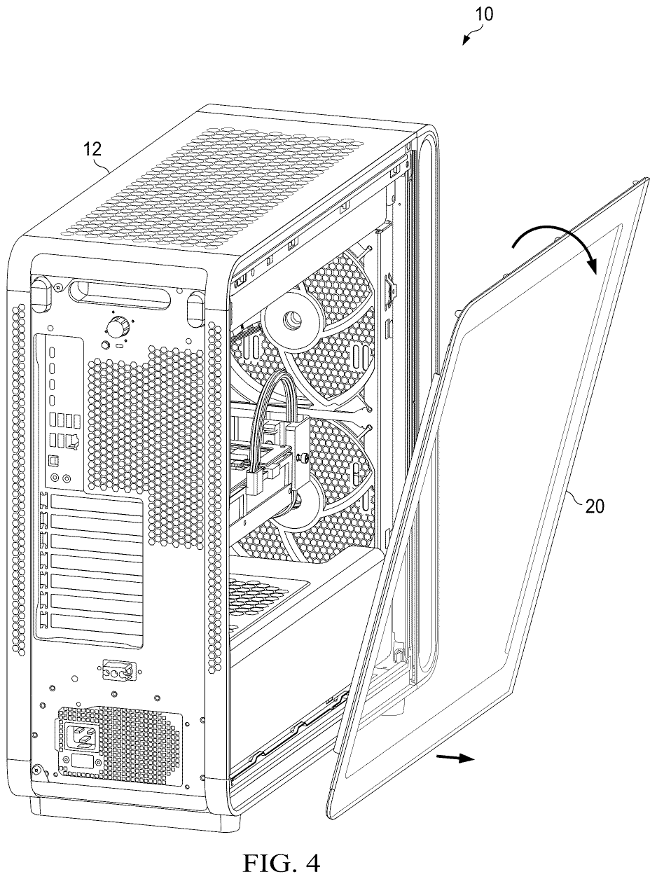

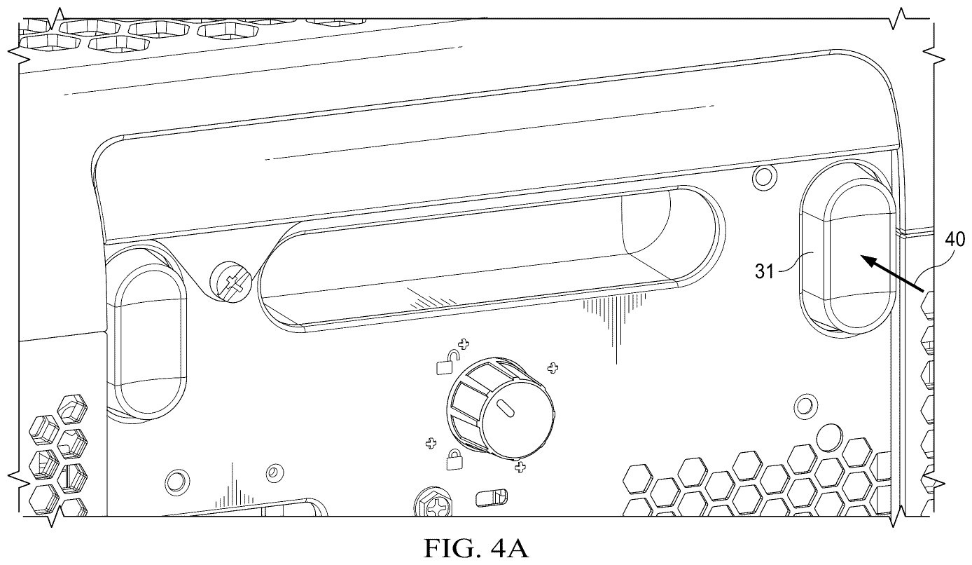

Referring now to FIGS. 4 and 4A, a rear side perspective view of information handling system 10 housing 12 depicts removal of transparent side cover 20 as a single actuation. FIG. 4A depicts a detailed view of the rear side with an arrow 40 indicating a frontward push on release button 31 allowed by rotation of the rotational member of the locking mechanism to an unlocked position. The inward press on release button 31 slides the latch of the transparent side cover forward to release hooks formed on the transparent side cover 20 from slots formed in the latch. FIG. 4 illustrates a release at the latch on the top side of transparent side cover 20 allowing a rotational movement of the top side of the transparent cover away from housing 12 so that the bottom side lifts free of a lip engagement on the bottom side of transparent side cover 20. In the example embodiment, all other housing covers remain in place and transparent side cover 20 is removed independent of the other housing covers.

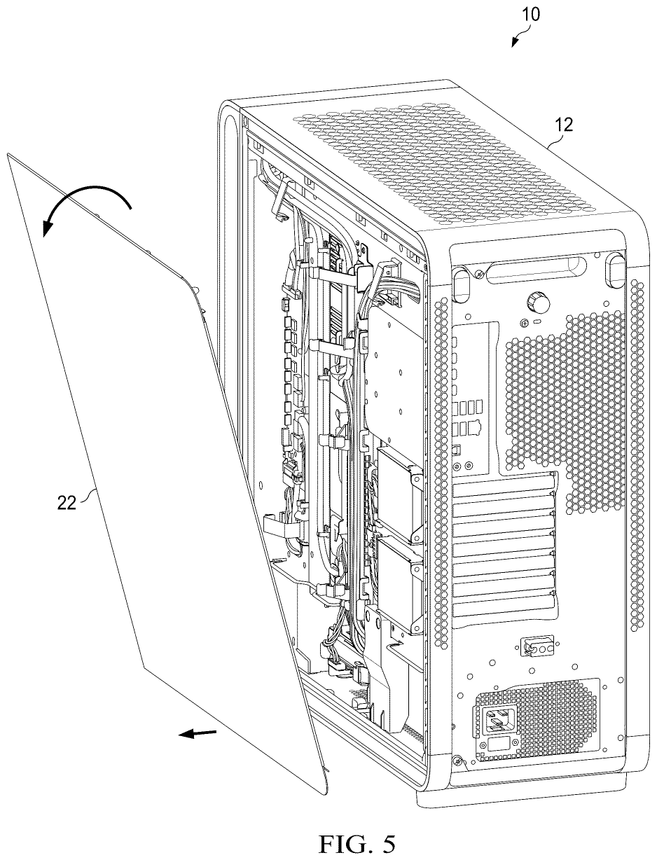

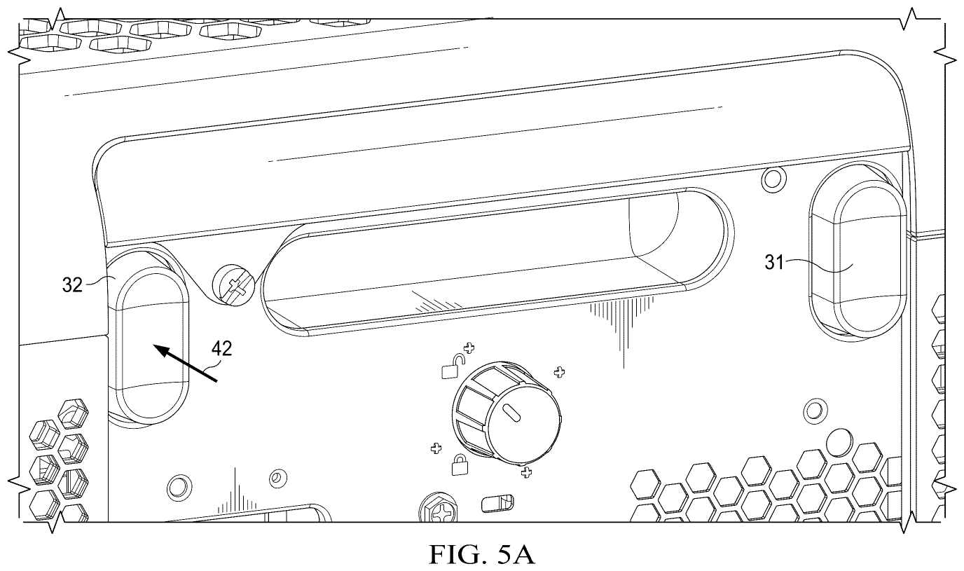

Referring now to FIGS. 5 and 5A, a rear side perspective view of information handling system 10 housing 12 depicts removal of the non-transparent side cover 22 as a single actuation. FIG. 5A depicts a detailed view of the rear side with an arrow 42 indicating a frontward push on release button 32 allowed by rotation of the rotational member of the locking mechanism to an unlocked position. The inward press on release button 32 slides the latch of the non-transparent side cover forward to release hooks formed on the non-transparent side cover 22 from slots formed in the latch. FIG. 5 illustrates a release at the latch on the top side of non-transparent solid side cover 22 allowing a rotational movement of the top side away from housing 12 so that the bottom side lifts free of a lip engagement on the bottom side of non-transparent solid side cover 22. In the example embodiment, all other housing covers remain in place and non-transparent side cover 22 is removed independent of the other housing covers.

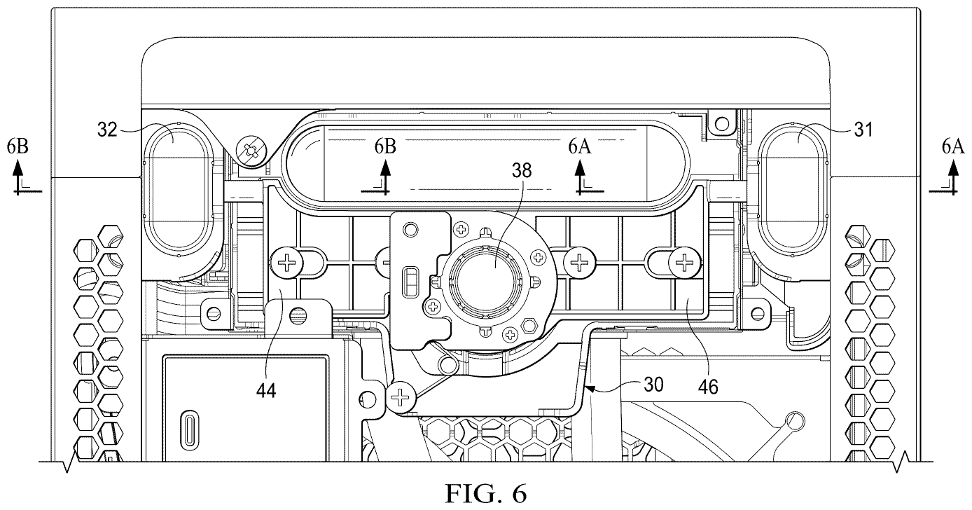

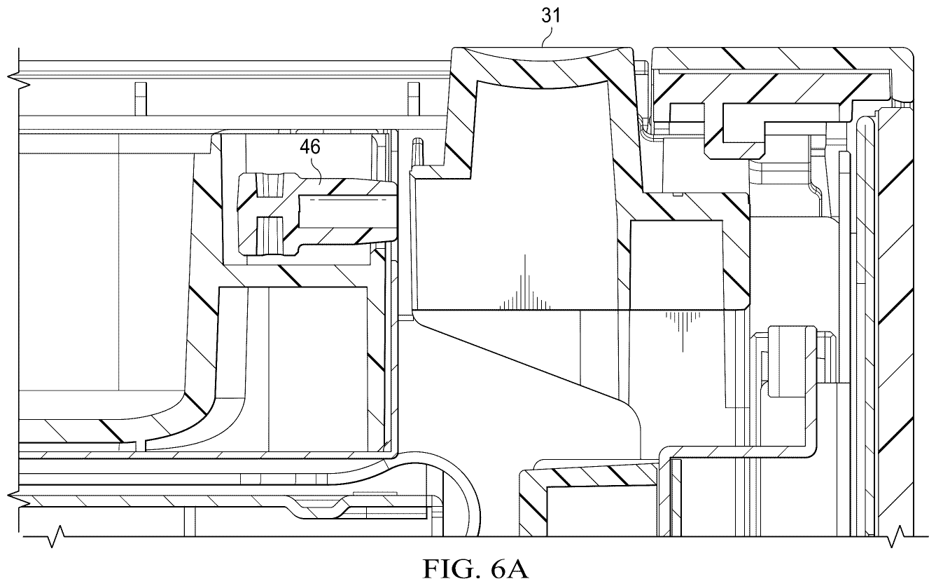

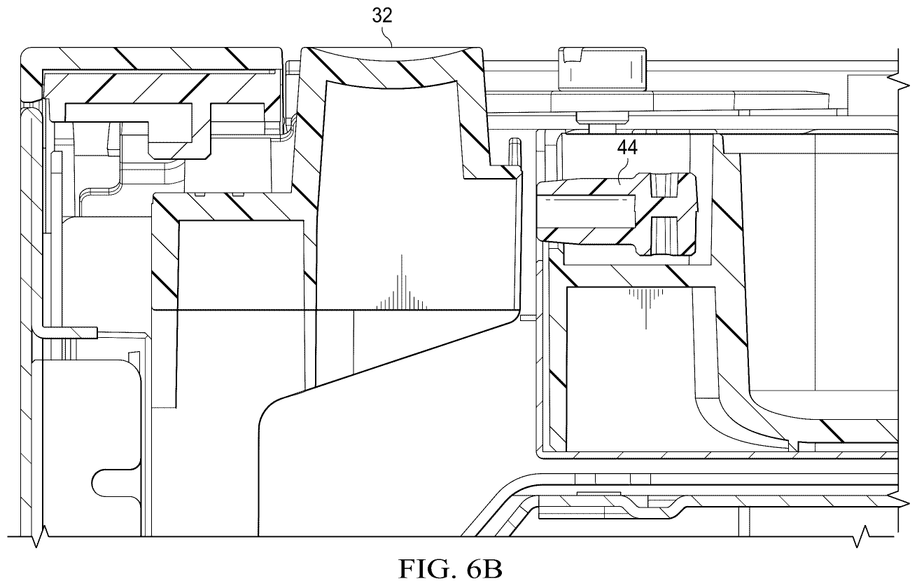

Referring now to FIGS. 6, 6A and 6B, rear side and sectional views of the locking mechanism 30 depict engagement of the side covers to the housing with the locking mechanism in an unlocked position. Rotational member 38 is rotated to the unlocked position with release buttons 31 and 32 biased rearward by a spring engagement of each latch with the housing inner chassis. Locking mechanism 30 is presented as a transparent view having a left locking pin 44 and a right locking pin 46 slid inward towards the rotational member 38 so that the locking pins are disengaged from the latch to allow a press at release buttons 31 and 32. FIG. 6A depicts a top sectional view of right locking pin 46 retracted from the left latch to allow the latch to move forward when the release button 31 is pressed. FIG. 6B depicts a top sectional view of left locking pin 44 retracted from the right latch to allow the latch to move forward when the release button 32 is pressed.

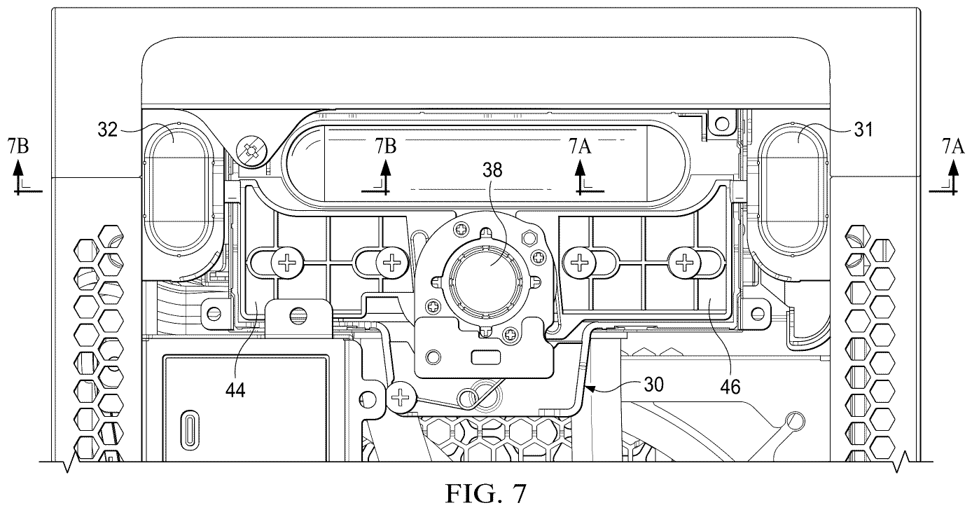

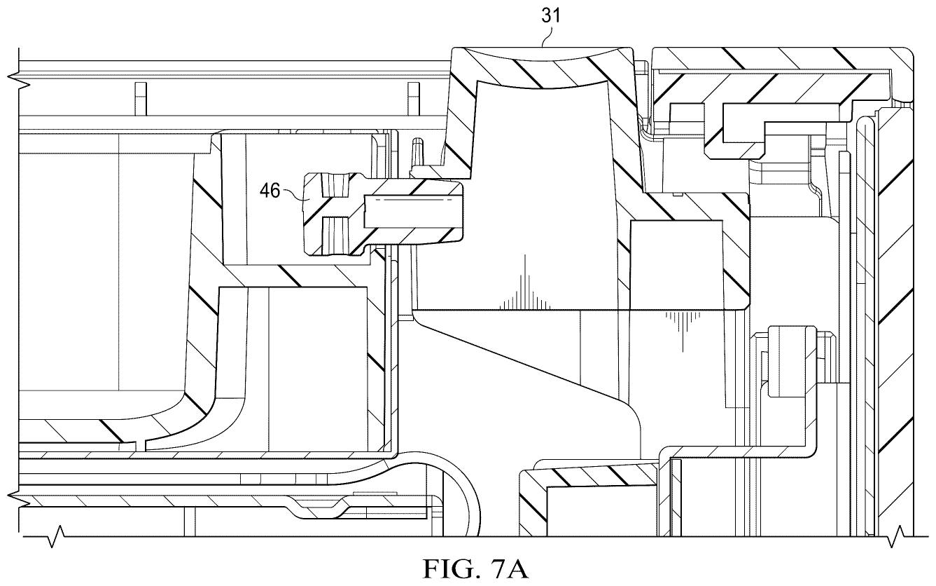

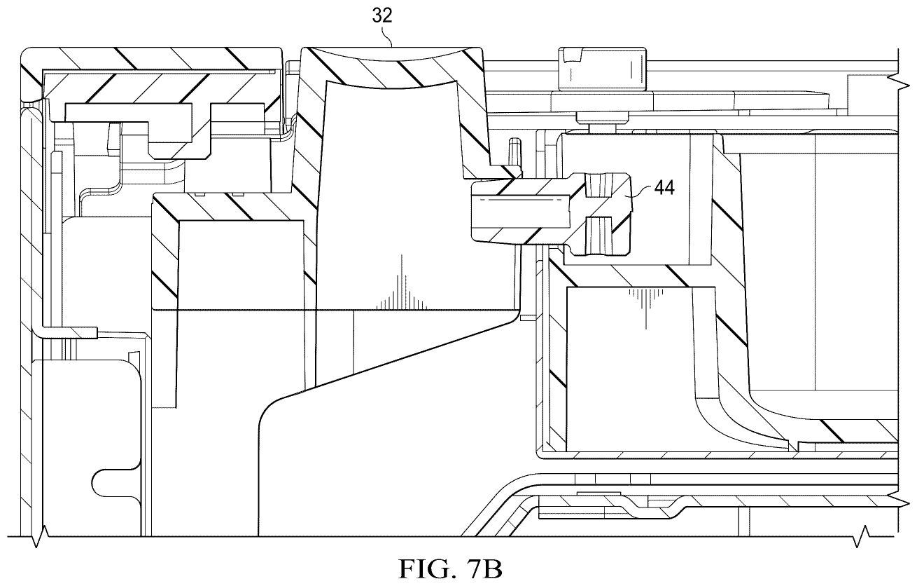

Referring now to FIGS. 7, 7A and 7B, rear side and sectional views of the locking mechanism 30 depict engagement of the side covers to the housing with the locking mechanism in a locked position. Rotational member 38 is rotated to the locked position with release buttons 31 and 32 biased rearward by a spring engagement of each latch with the housing inner chassis. Locking mechanism 30 is presented as a transparent view having a left locking pin 44 and a right locking pin 46 slid outward away from the rotational member 38 so that the locking pins are engaged in the latch to prevent a press at release buttons 31 and 32. FIG. 7A depicts a top sectional view of right locking pin 46 inserted into the left latch to prevent the latch from moving forward when the release button 31 is pressed. FIG. 7B depicts a top sectional view of left locking pin 44 inserted into the right latch to prevent the latch from moving forward when the release button 32 is pressed. Although the example embodiment depicts a rotational member that rotates only between locked an unlocked positions and that simultaneously locks and unlocks both locking pins, alternative embodiments may asynchronously move the locking pins to unlock only one locking pin at a time.

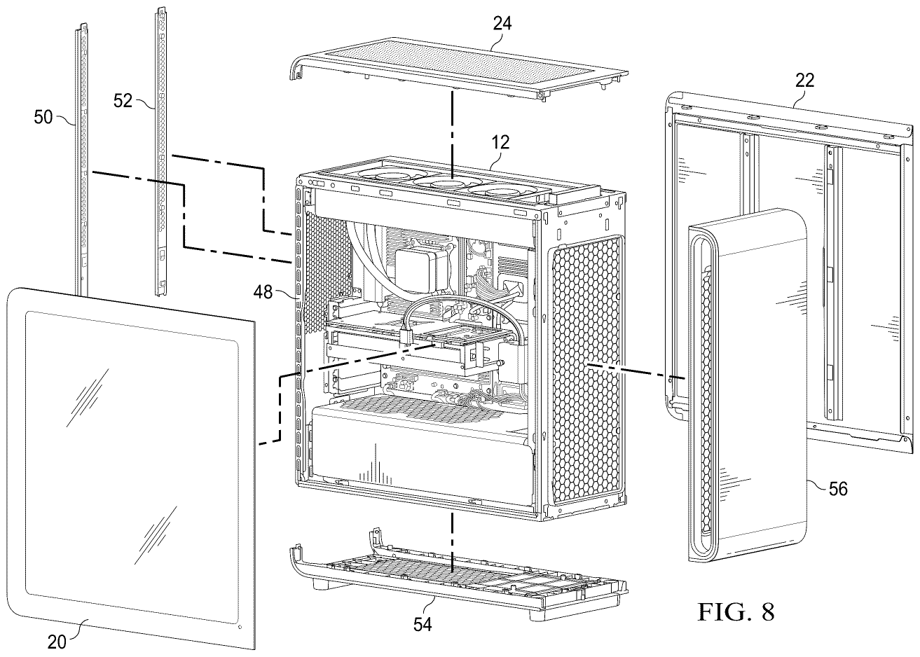

Referring now to FIG. 8, a front left exploded perspective view depicts a full breakdown of housing 12 once the lock is unlocked and the side covers are removed. An inner chassis 48 has a central structure that supports the internal components, such as the motherboard, and the external housing covers. As is described above, a single locking mechanism secures all of the housing covers when assembled and locked. Once the locking mechanism is released, the housing covers release from inner chassis 48 in a defined order. The left transparent side cover 20 and right non-transparent cover 22 each separate from inner chassis 48 by actuation of their respective release buttons. A top cover 24 is the next primary housing cover that secures the other housing covers so that the top cover must be released before other covers can be removed. Top cover 24 couples in places in part by a pin of transparent side cover 20 passed through an opening of top cover 24 so that transparent side cover 20 must be removed to remove top cover 24. Rear trim 50 and 52 engages top cover 24 and a bottom cover 54 so that removal of the trim requires removal of transparent side cover 20 and top cover 24. Once trim 50 and 52 is removed bottom cover 54 will separate from inner chassis 48. A front cover 56 can then be removed provided that the non-transparent side cover 22 is also removed. Each of the covers is thereby locked in place by the single locking mechanism when all are assembled to chassis 48 yet the side covers are removable to allow ready end user access to the housing interior when removed in the defined order. The entire housing from the lock mechanism to removal of the front cover is accessed in a toolless manner. In an alternative embodiment, a tooled entry may be required, such as by securing the lock mechanism with a safety screw.

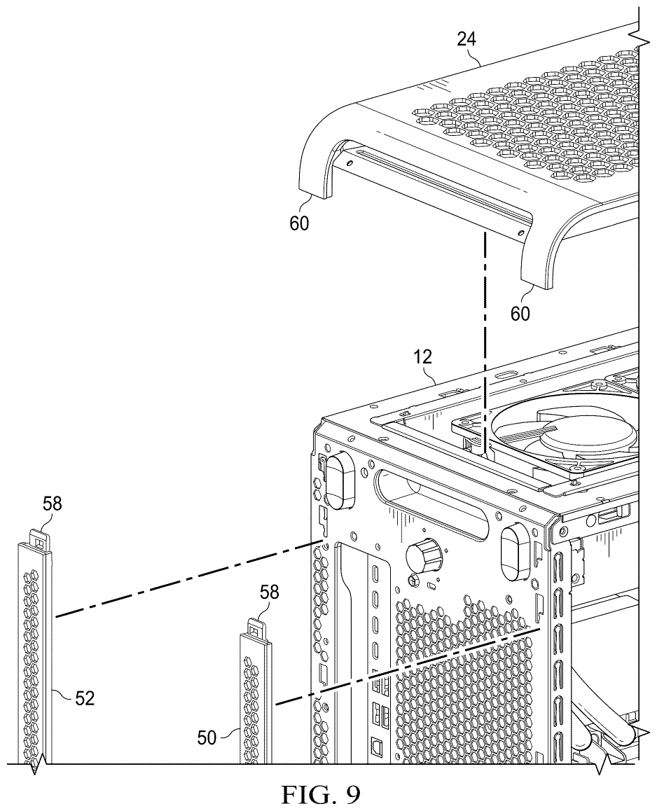

Referring now to FIG. 9, an upper rear perspective view depicts the housing top cover 24 exploded from the housing 12. An extension 58 from each end of trim 50 and 52 inserts into a slot of top cover 60 so that trim 50 and 52 cannot be separated from the housing unless top cover 24 is first lifted free from housing 12. Once top cover 24 is lifted from housing 12, trim 50 and 52 are freed to lift from the bottom cover as described in greater detail below. While cover 24 is in place on the top side of housing 12, trim 50 and 52 are retained in place.

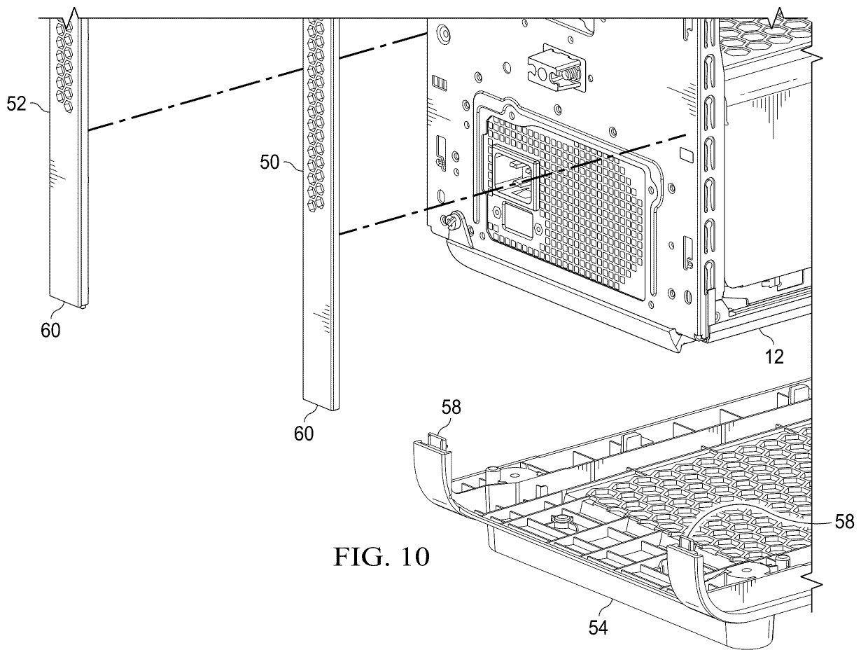

Referring now to FIG. 10, an upper rear perspective view depicts the housing bottom cover exploded from housing 12. Extensions 58 from bottom cover 54 extend upwards and into slots 60 at the bottom side of trim 50 and 52. When the top cover is removed, trim 50 and 52 lift up to release bottom cover 54, which can then be separated from the housing by pulling the bottom cover rearward to separate from the front cover.

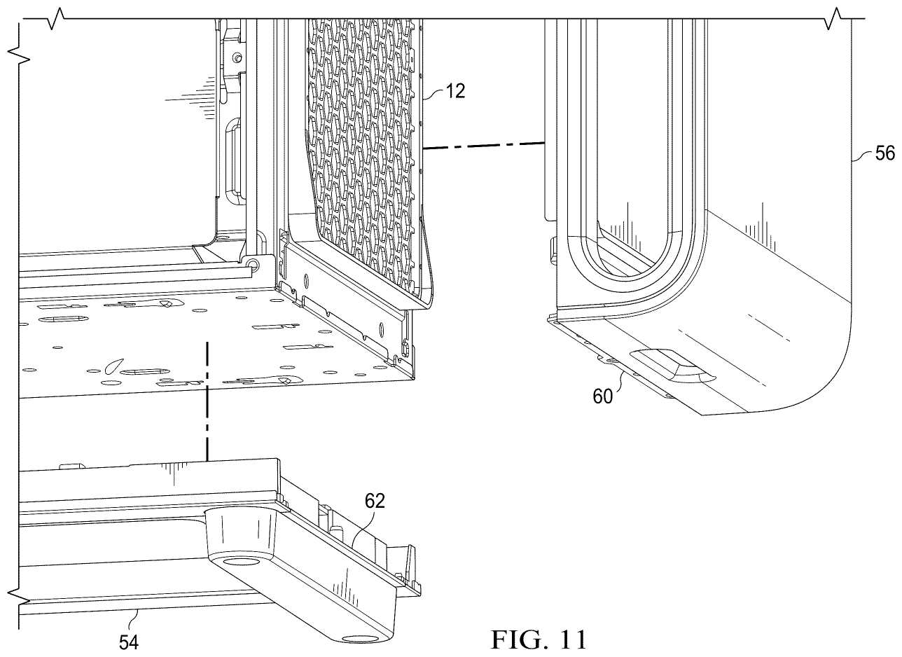

Referring now to FIG. 11, a front lower perspective exploded view depicts front cover 56 separated from bottom cover 54. An extension 60 of front cover 56 inserts into a slot 62 of bottom cover 54 to prevent separation of front cover 56 until bottom cover 54 is removed. In addition, front cover 56 couples to the transparent and non-transparent side covers as described in greater detail below so that removal of front cover 56 requires removal of all other housing covers. In alternative embodiments, different relationships of the interlocking components of the housing cover may adjust the order in which the housing covers are removed and which housing covers are removed for particular types of housing access. For example, in one embodiment removal of one side cover may release all of the other housing covers for independent removal.

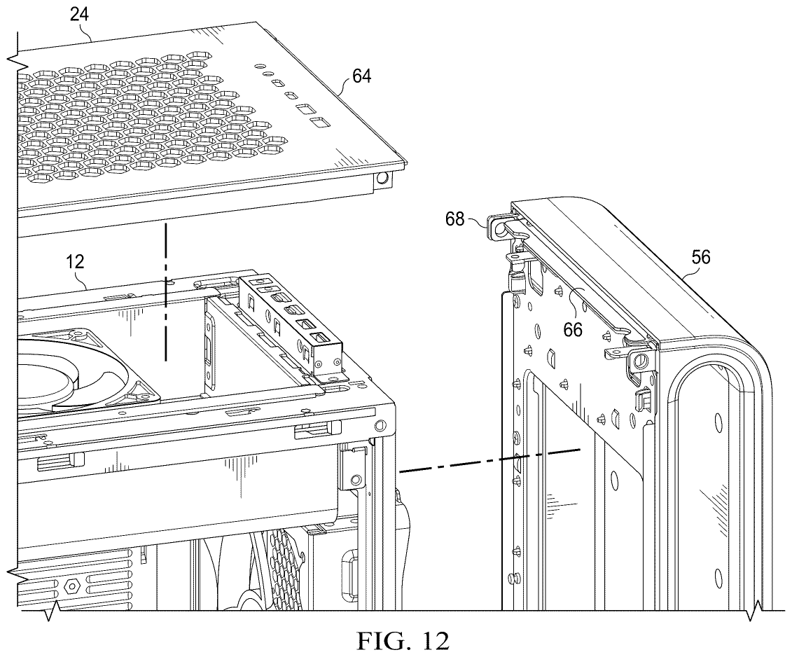

Referring now to FIG. 12, a rear upper perspective exploded view depicts the front cover 56 and top cover 24 separate from housing 12. Front cover 56 has an extension 66 that engages in a slot 64 formed in top cover 24 so that top cover 24 is removed to release front cover 56. In addition, front cover 56 has a tab 68 with a central opening that accepts a pin inserted from the non-transparent side cover on one side and the transparent side cover on the opposite side. Engagement of the pin as detailed below when the side covers are present prevents the removal of front cover 56.

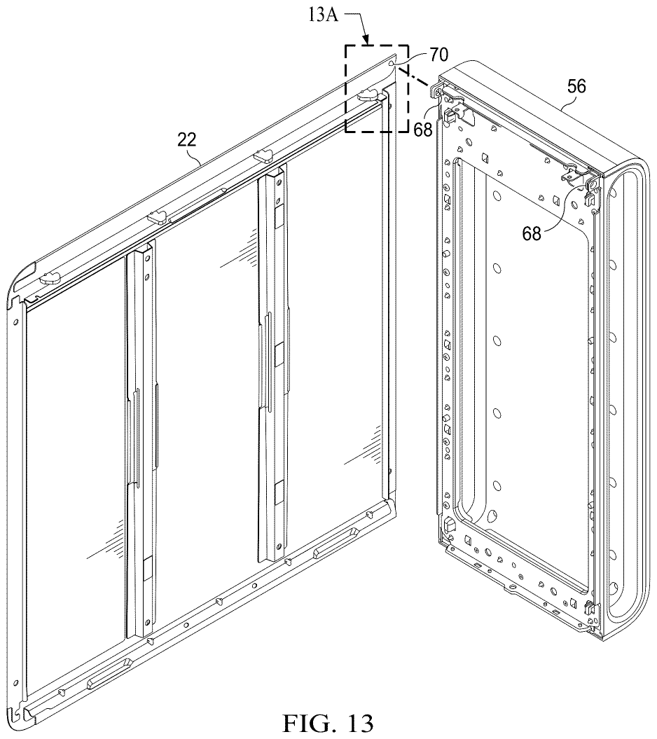

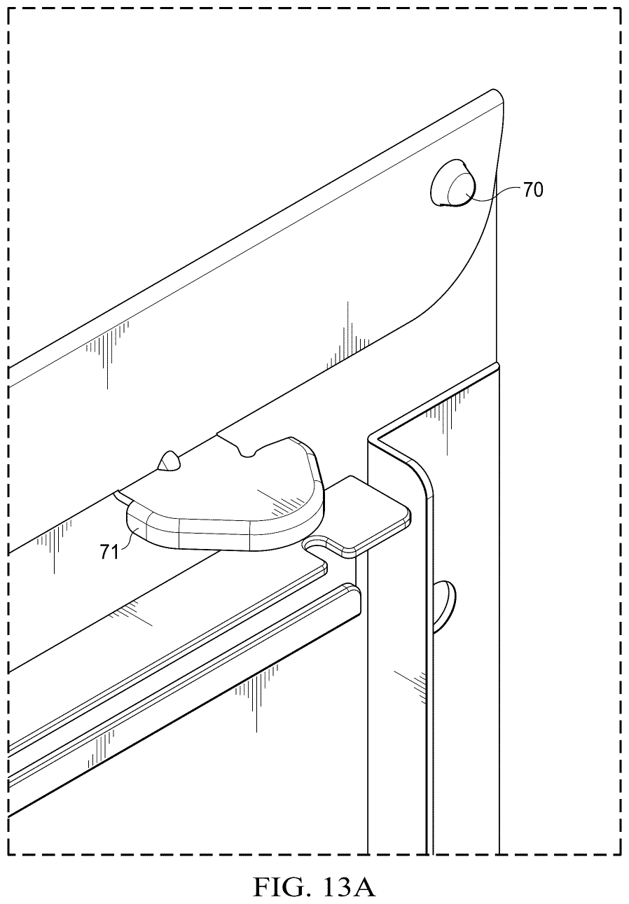

Referring now to FIGS. 13, 13A and 13B, engagement of non-transparent solid side cover 22 with front cover 56 is depicted. In the example embodiment, FIG. 13 depicts a location on non-transparent side cover 22 of a protruding embossed member 70 that engages with one of the tab 68 openings of front cover 56. FIG. 13A depicts a detailed view of protruding embossed member 70 near a hook 71 that engages with a slot of the latch as described above. FIG. 13B depicts a top sectional view of protruding embossed member 70 extending from non-transparent solid side cover 22 into the opening of tab 68 to secure front cover 56 to the housing inner chassis when the side cover is coupled to the housing.

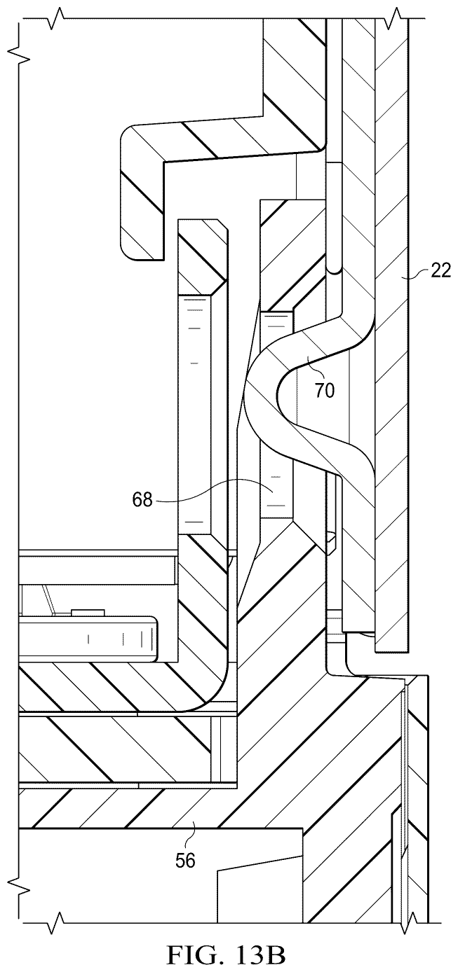

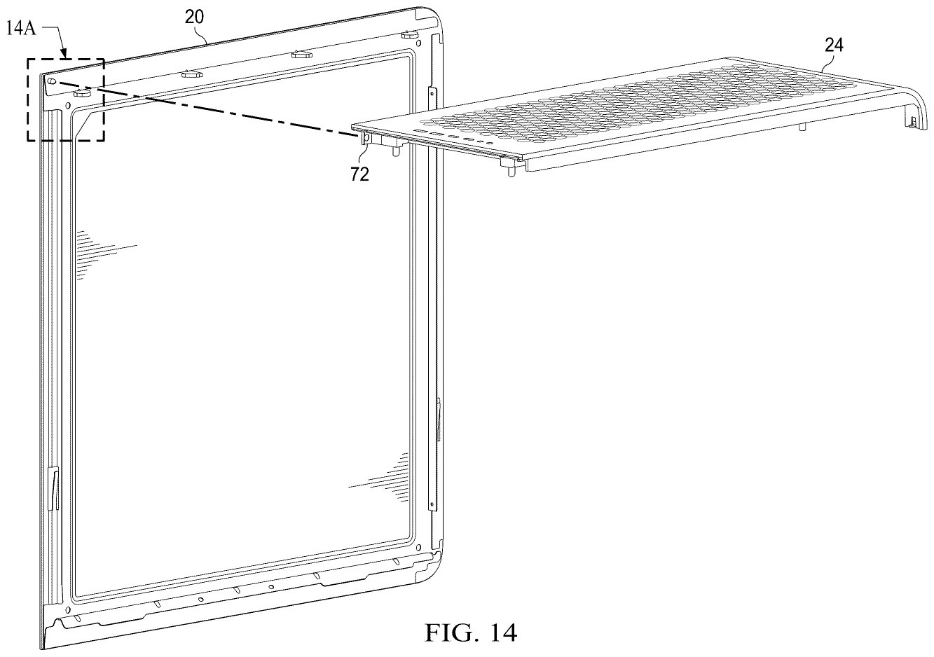

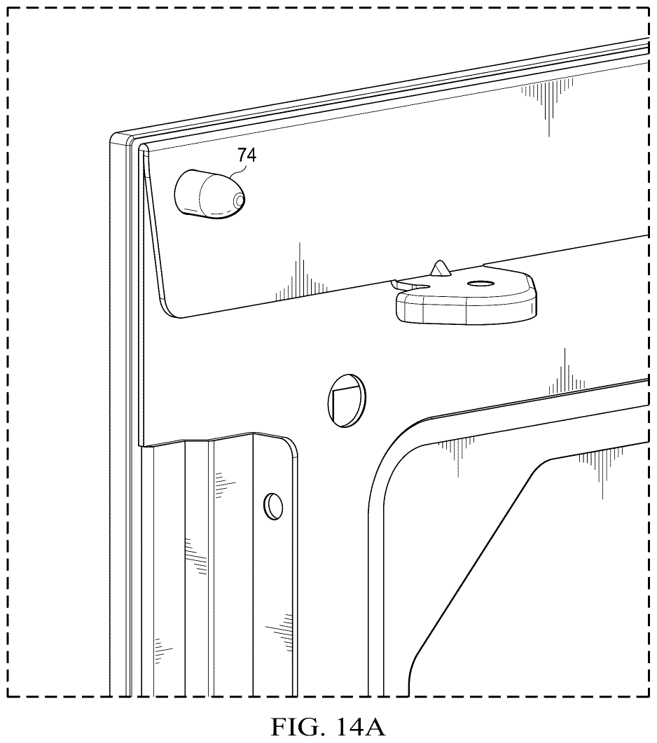

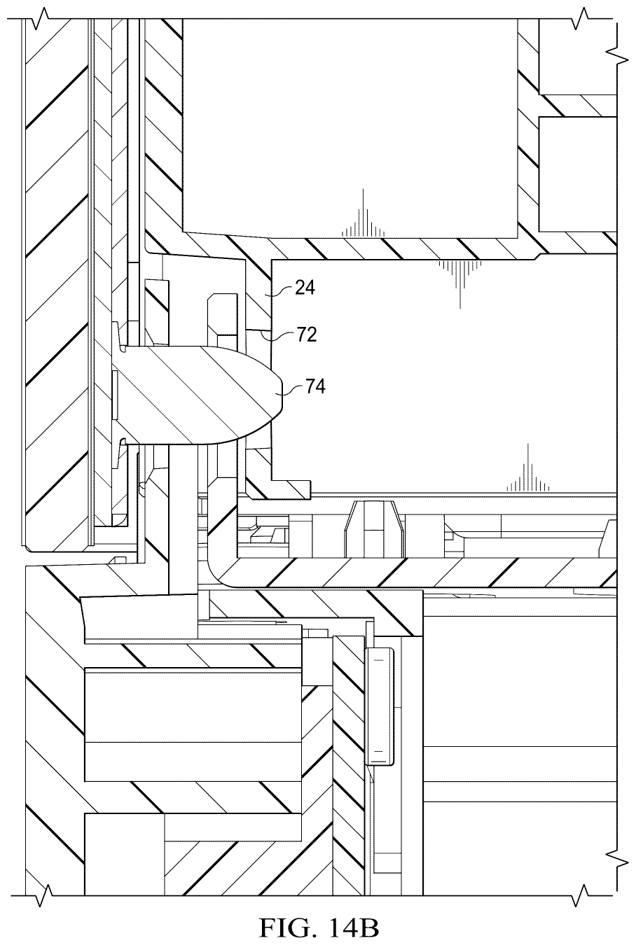

Referring now to FIGS. 14, 14A and 14B, engagement of transparent side cover 20 with front cover 56 is depicted. In the example embodiment, FIG. 14 depicts a location on transparent side cover 20 of a pin 74 that engages with one of the openings 72 of top cover 24 so that the top cover is coupled in place until removal of the transparent side cover removes the pin from the opening. FIG. 14A depicts a detailed view of pin 74 near a hook that engages with a slot of the latch as described above. FIG. 14B depicts a top sectional view of pin 74 extending from transparent side cover 20 into the opening 72 of top cover 24 to hold the top cover in place until the transparent side cover is removed. In addition, pin 74 may insert into the opening of the tab of the front cover to secure the front cover to the housing inner chassis when the transparent side cover is coupled to the housing. In this manner, both side covers must be removed to separate the front cover from the housing. In alternative embodiments, other orders for the cover removal may be used, such as having only one side cover removed to release the front cover.

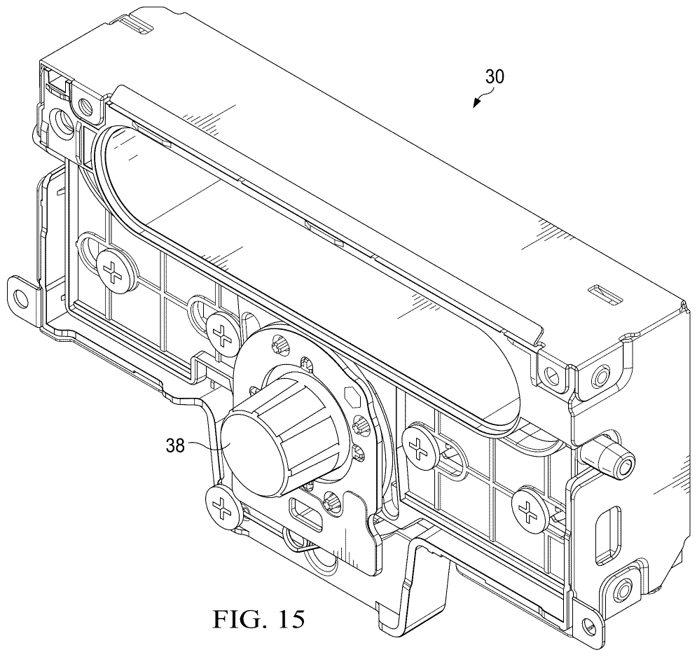

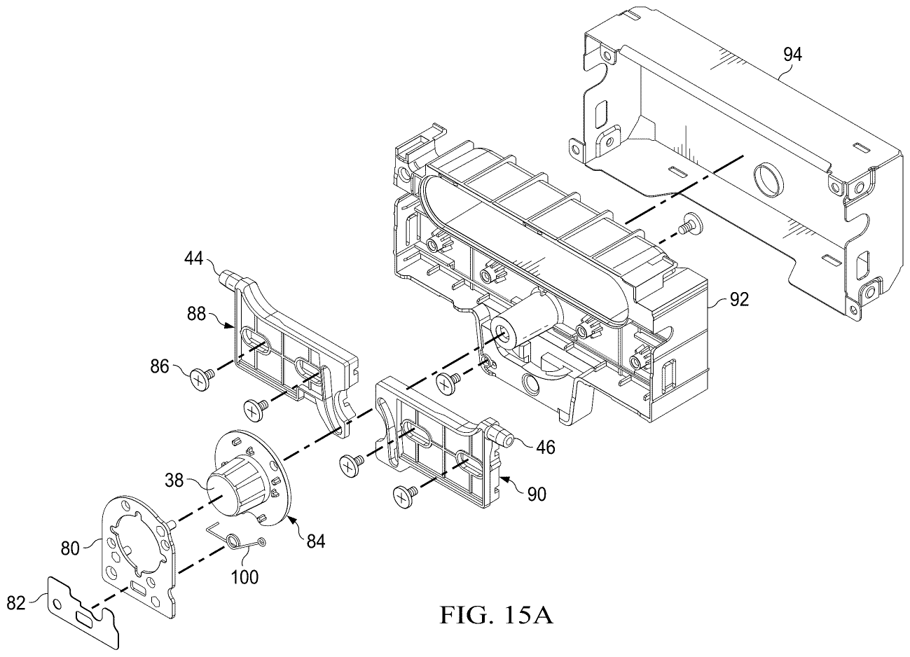

Referring now to FIGS. 15 and 15A, front perspective and exploded views depict locking mechanism 30 having locking pins that actuate in opposing directions. Rotational member 38 extends outward and through an opening of the housing to accept an end user selection of locked and unlocked. In the example embodiment, locking mechanism 30 is a single point locking system so that when the housing covers are in place on the housing as described above, rotation to the locked positions ensures that all housing covers are secured. Thus, engagement of an external locking device, such as a padlock or Kennsington lock, that prevents rotation of the rotational member also prevents access to the housing interior.

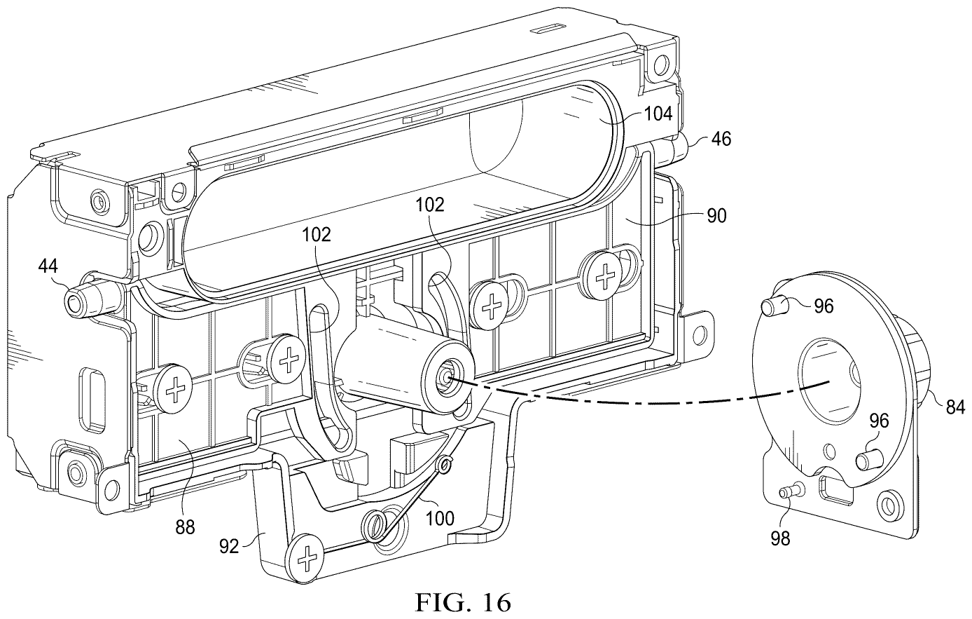

FIG. 15A depicts assembly of one example of the locking mechanism 30 that supports rotation between a locked and unlocked position. Pins (shown in FIG. 16) extending from a front side of rotational member 38 insert into openings of a rotating bracket 80 that defines a rotational range. A piece of Mylar 82 between rotating bracket 80 and rotational member 84 reduces friction associated with rotation along with resulting wear. A set of screws 86 insert through slots formed in a left locking pin member 88 and a right locking pin member 90 to couple to an internal frame 92 in which the locking pin members slide. A left locking pin 44 and right locking pin 46 extend away from rotational member 38 to engage the housing latch and retract towards rotational member 38 to release the housing latch. A spring 100 held in internal frame 92 creates a bias that works to keep the locking pin members in either the locked or unlocked position. One of the screws 86 enters from the backside of internal frame 92 to engage rotational member 38 and hold the assembly in the internal frame. Internal frame 92 snaps into place in an external frame 94 that in turn couples to the housing.

Referring now to FIG. 16, locking mechanism 30 is depicted with the rotational member 84 removed to illustrate engagement of the rotational member with the locking pins. First and second pins 96 extend out from a bottom side of rotational member 84 and into cammed slots 102 formed in locking pin members 88 and 90. Spring 100 couples to inner frame 92 to bias the locking pin members to either a fully retracted or fully extended position. Cammed slots 102 translate rotational movement of rotational member 84 into lateral movement of locking pins 44 and 46 to extend or retract the locking pins with opposing motion of locking pin members 88 and 90 in response to a rotation. In the example embodiment, locking pins 44 and 46 move synchronously to extend and retract together by laterally sliding towards rotational member 84 when rotated to the unlocked position and laterally sliding away from rotational member 84 when rotated to the locked position. In alternative embodiments, the cammed slot shapes may be altered to provide sequential movement of locking pins 44 and 46 so that one side cover unlocks before the other. In various embodiments, the cammed slots may support unlock of one side with rotation in one direction and unlock of the other side with rotation in another direction. In the example embodiment, a handle 104 is formed in internal frame 92 to provide a lifting point for the information handling system when the locking mechanism is installed.

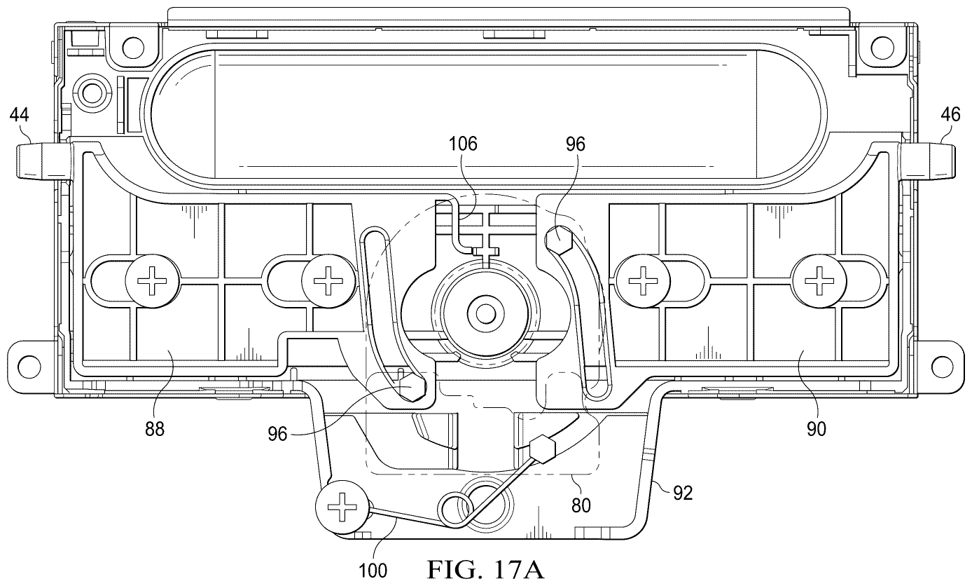

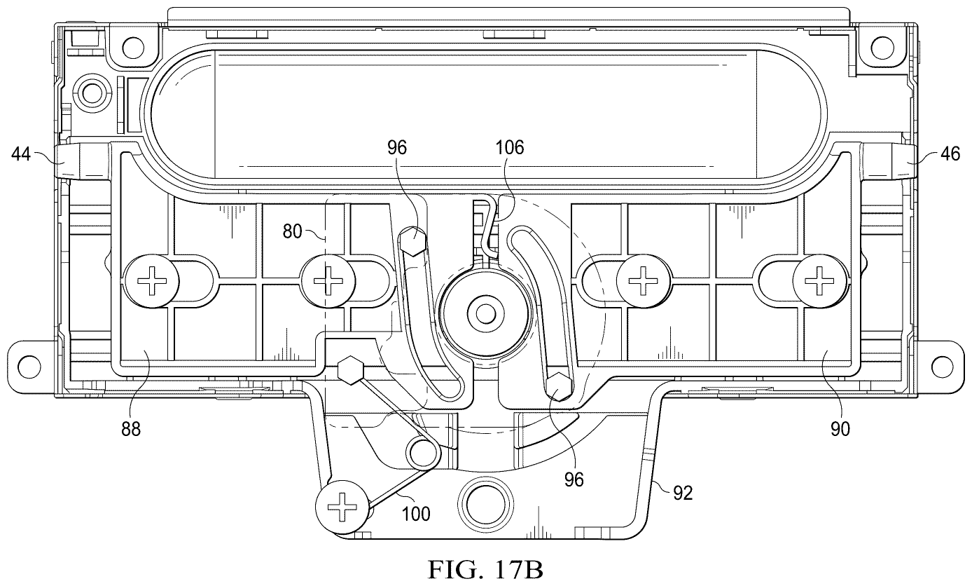

Referring now to FIGS. 17A and 17B, a front sectional view of the locking mechanism depicts the location of pins 96 in cammed slots 102 when rotational member 84 is in the locked and unlocked position. FIG. 17A depicts a locked position with rotating bracket 80 shown hashed and pins 96 in each cammed slot. Locking pin members 88 and 90 are laterally slid away from rotational member 86 to extend locking pins 44 and 46, and spring 100 biases the locking pin members outward. In the example embodiment, a compression feature 106 extends out from locking pin member 88 towards locking pin member 90. A screw or other mechanical attachment device inserted into internal frame 92 holds the locking pin members in a sliding position. FIG. 17B depicts an unlocked position in which rotating bracket 80 rotates approximately 90 degrees with the rotational member to an unlocked position having locking pins 44 and 46 retracted into internal frame 92. Pins 96 rotate with the rotational member to an opposite side of each cammed slot to slide the locking pin members 88 and 90 towards the rotational member. Compression feature 106 of locking pin member 88 presses against locking pin member 90 to limit the motion inward as the pins travel to the end of the cammed slots. In addition, compression feature 106 creates a spring force between locking pin members 88 and 90 when in the unlocked position so that the tension avoids rattling and vibrating in the unlocked position.

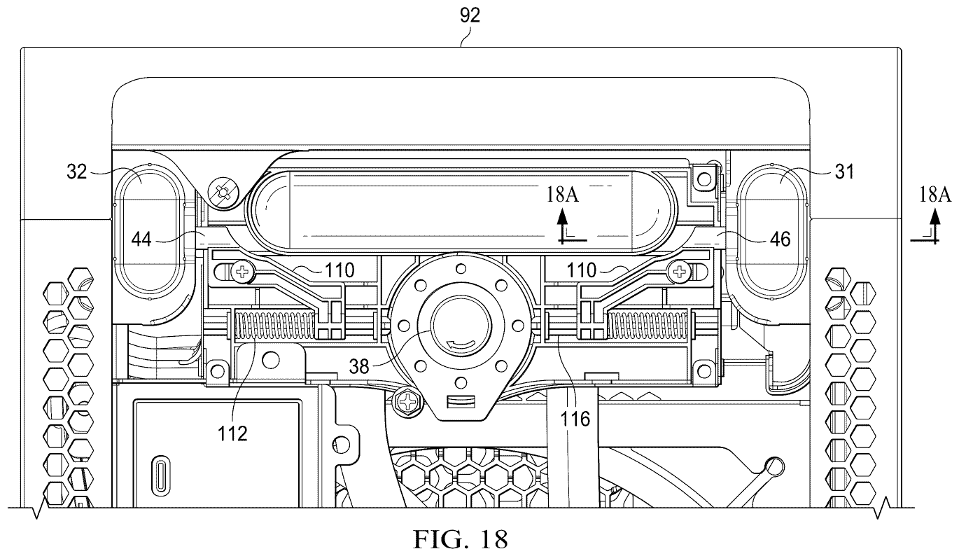

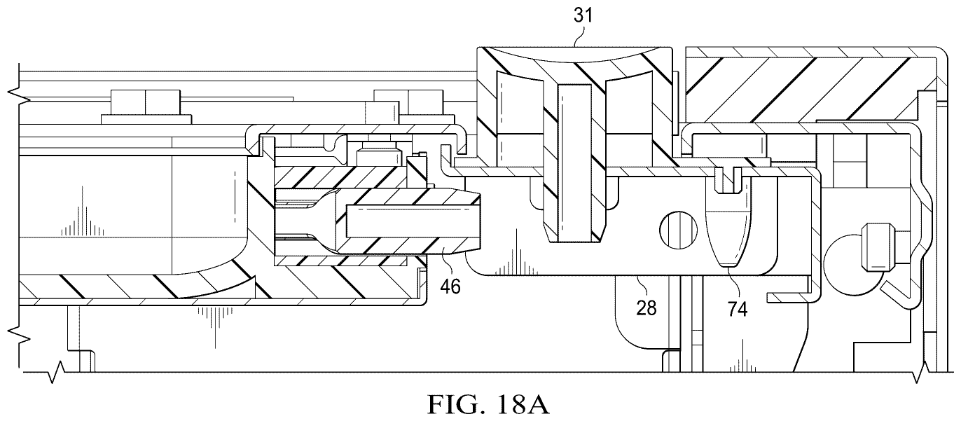

FIGS. 18 and 18A depict an alternative embodiment of locking mechanism 30 in a locked position having locking pins traveling laterally motivated by a cam surface of the rotational member. In the locked position of FIG. 18, springs 112 placed on a lateral arm 116 biases locking pins 44 and 46 towards an unlocked position at a support arm 110. Rotational member 38 has a cammed internal surface with an increased diameter in the locked position that overcomes the bias of springs 112 to push locking pins 44 and 46 out of internal frame 92 to engage a latch 28 and 26 so that release buttons 31 and 32 will not press inward. FIG. 18A depicts a sectional view having locking pin 46 inserted into latch 28 to prevent latch movement and prevent movement of button 31 when pressed inward. A pin 74 of the transparent side cover is captured in the latch to prevent removal of the side cover unless the latch is actuated.

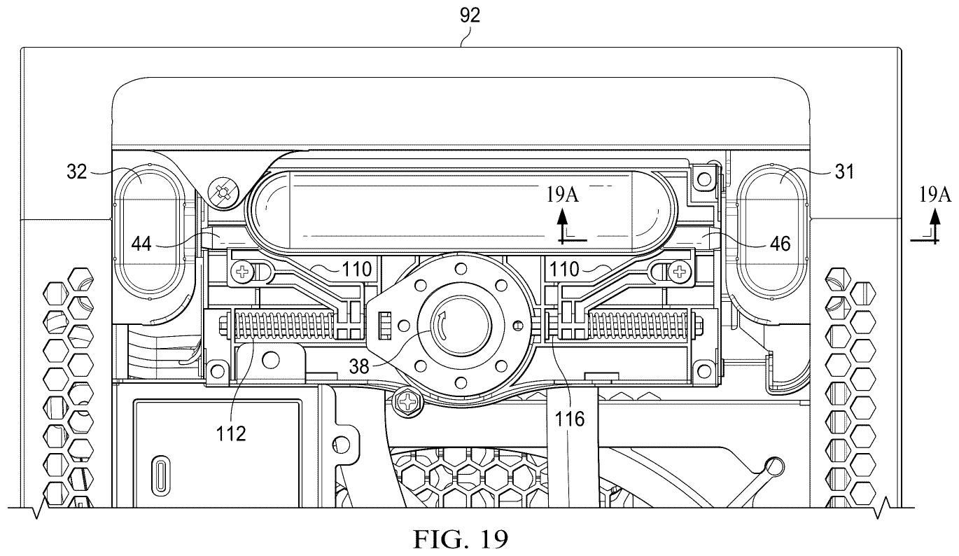

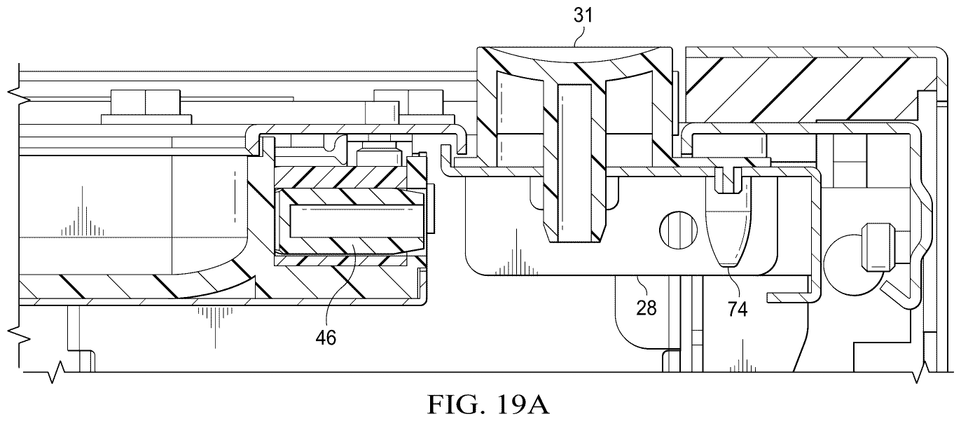

Referring now to FIGS. 19 and 19A, locking mechanism 30 alternative embodiment is depicted in an unlocked position. Rotational member 38 rotates the cam inner surface to align a smaller diameter with lateral arm 116 so that spring 112 presses the locking pins inward towards the rotational member leaving button 31 and 32 free to accept an end user press that actuates latch 28 and 26. FIG. 19A depicts a sectional view showing the locking pin 46 retracted from the latch 28 to allow latch movement and release of the transparent side cover when button 31 is pressed inward.

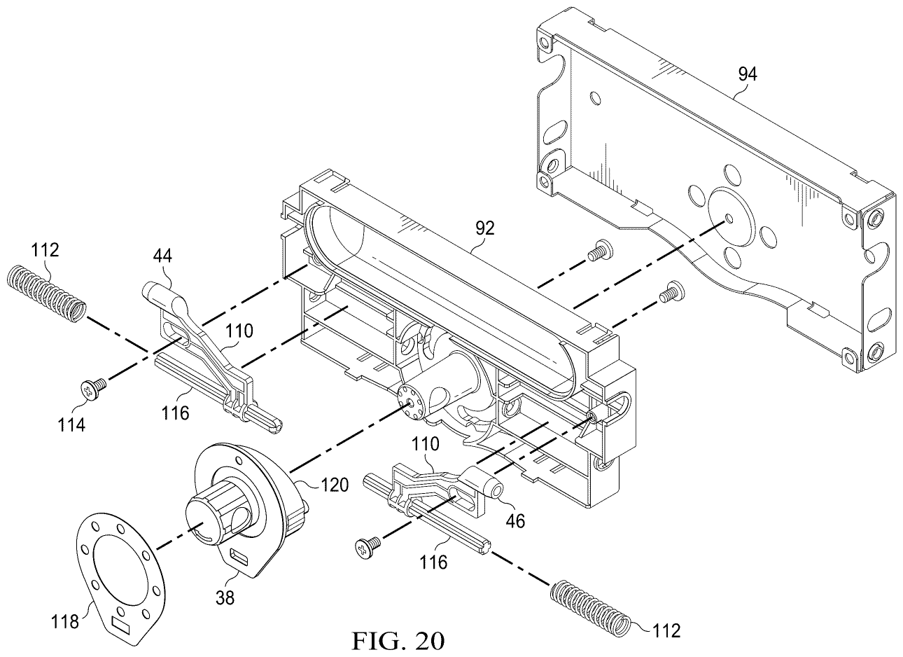

Referring now to FIG. 20, a front perspective exploded view depicts locking mechanism 30 with a cam 120 on the inner side of rotational member 38. Springs 112 insert on lateral arms 116 and a support arm 110 couples by a screw 114 to inner frame 92. A mylar ring 118 inserts onto rotational member 38 to reduce friction when the rotational member is rotated between locked and unlocked. Cam 120 has a variable diameter that, when rotated, presses lateral arms 116 out in the locked position and allows springs 112 to retract lateral arms 116 inward in the unlocked position. Inner frame 92 couples to outer frame 94 and the assembly couples to the information handling system housing.

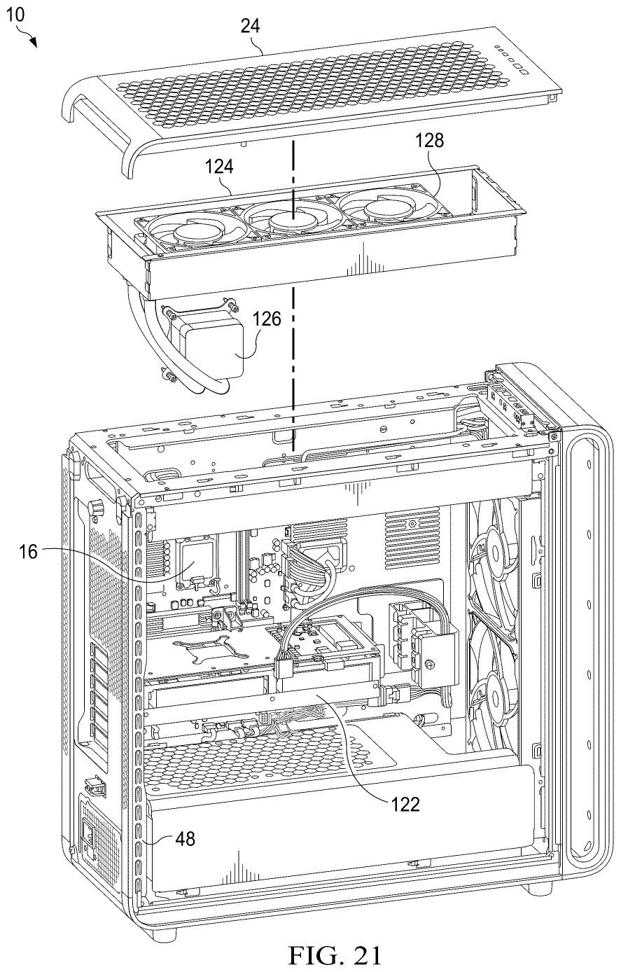

Referring now to FIG. 21, a rear side perspective exploded view depicts information handling system 10 having a liquid cooling assembly 124 mounted under a housing top cover 24. A rectangular mounting rim defined in the housing inner chassis 48 accepts a rectangular mounting frame of liquid cooling mounting assembly 124 with an intake of cooling airflow through a filter coupled in housing top or bottom cover 24. For instance, cooling airflow is accepted through the top and bottom filters and exhausted out the housing rear side. In the example embodiment, the rectangular mounting frame supports DIY end user modifications by accepting a wide variety of different sized liquid cooling modules, such as 240, 280, 360, and 420 mm liquid cooling modules. To achieve this adaptability, the mounting frame includes four different sized blanks that adapt the air passage to each size liquid cooling module so that air passes through the cooling fans and does not recycle through the housing. In addition to providing a right-sized air passage for the selected liquid cooling module, the mounting frame shields EMI from passage through the top housing cover. The mounting frame is readily accessible from the housing top cover for each of modification and service, in some cases without removing the liquid cooling assembly itself. In the various embodiments, a pump 126 of the liquid cooling assembly 124 directs cooling fluid through one or more thermal transfer devices 128, such as a radiator, heat sink, etc., that couple to the system CPU 16 and/or GPU 122. In the example embodiment, liquid cooling assembly 124 under the housing top cover cools CPU 16. The heated air passing from the exterior through the filter and into liquid cooling assembly 124 is exhausted out the system rear side. A separate liquid cooling assembly may be include for the GPU mounted at the system front so that multiple liquid cooling systems may be installed and may be interchangeable by an end user between the CPU and GPU.

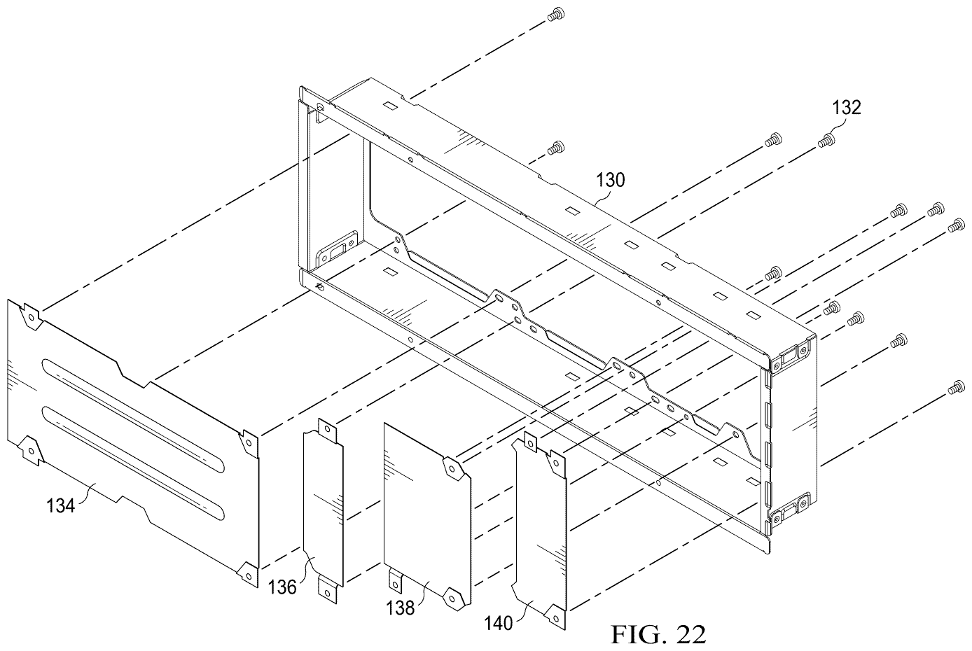

Referring now to FIG. 22, a top perspective exploded view depicts an example embodiment of a liquid cooling mounting frame 130. In the example embodiment, mounting frame 130 is made of conductive material, such as formed from sheet metal, to have an outer perimeter lip that couples over the inner frame of the information handling system housing. Screws 132 insert through a lower side of mounting frame to couple with mounting blanks 134, 136, 138 and 140, which are formed from sheet metal. Each blank is removed as needed to accept a liquid cooling module of a desired size. In one embodiment, the blanks may overlap each other to help reduce air leakage and to help suppress EMI.

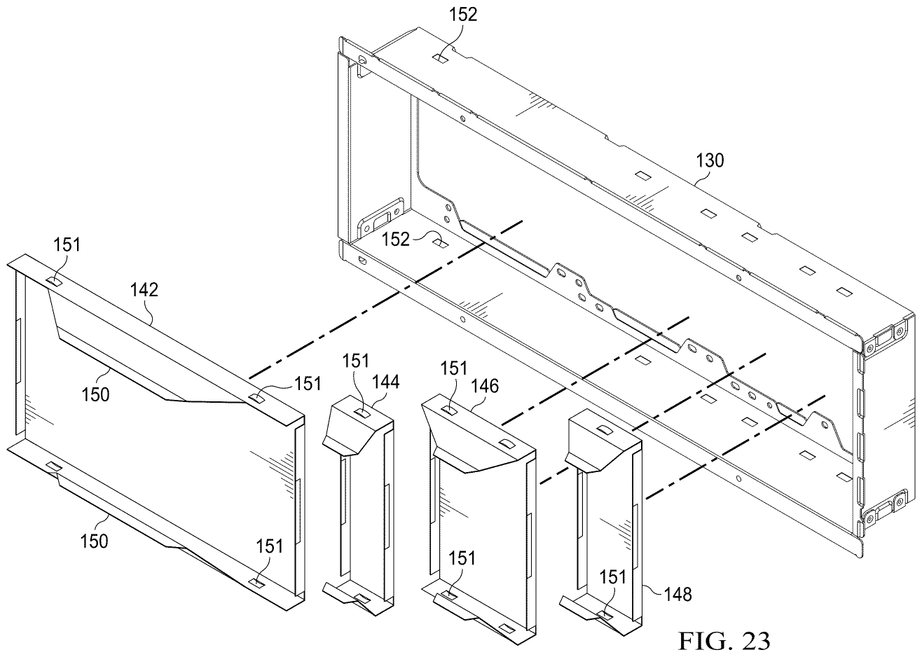

Referring now to FIG. 23, a top perspective exploded view depicts another example embodiment of a liquid cooling mounting frame 130. In the example embodiment, mounting frame 130 is made of conductive material, such as formed from sheet metal, to include internal snap formations 152 that couple with snaps 151 so that a snap release feature 150 that squeezes also releases the snaps to remove the blanks. The blanks are formed from shaped sheet metal of blanks 142, 144, 146 and 148. Each blanks snaps into place and is selectively released by actuation of the snaps as needed to add or remove a liquid cooling module.

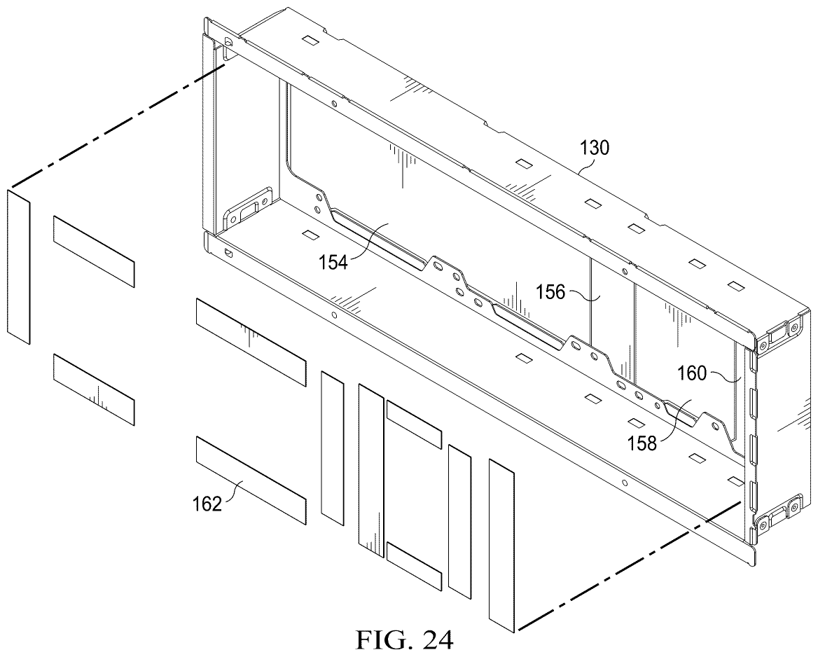

Referring now to FIG. 24, a top perspective exploded view depicts another example embodiment of a liquid cooling mounting frame 130. In the example embodiment, mounting frame 130 is formed from cut and bent sheet metal to have knockouts defined by perforations cut between mounting frame 130 and knockout blanks 154, 156, 158 and 160. Mylar pieces 162 couple over the perforation openings to prevent airflow leaks through the frame with the housing. When a liquid cooling module is coupled in place, the size of the liquid cooling module is defined by pressing out the appropriate number of blanks and removing the mylar.

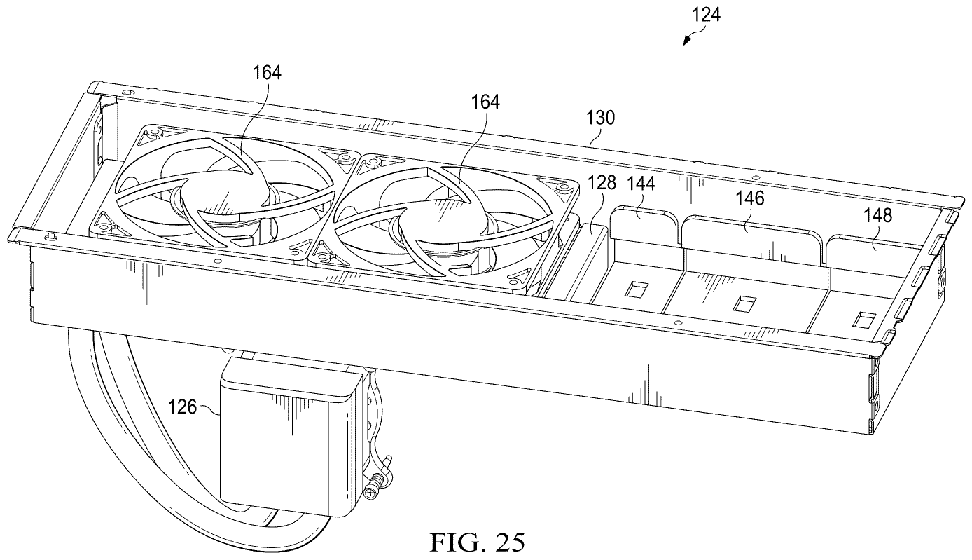

Referring now to FIG. 25, an upper perspective view depicts one example of the mounting frame 130 of a liquid cooling assembly 124 supporting a liquid cooling module with only a portion of the mounting frame surface area used. In the example embodiment, one blank is removed from mounting frame 130 and one liquid cooling module 164 having a size of 240 mm and two fans couples into the mounting frame with a single liquid cooling pump 126. The three blanks 144, 146 and 148 cover the opening in the bottom side of mounting frame 130 so that cooling airflow is passed through mounting frame 130 only through liquid cooling module 164. Each of blanks 144, 146 and 148 have different sizes corresponding to liquid cooling module size that could be selected by an end user to fit into the mounting frame.

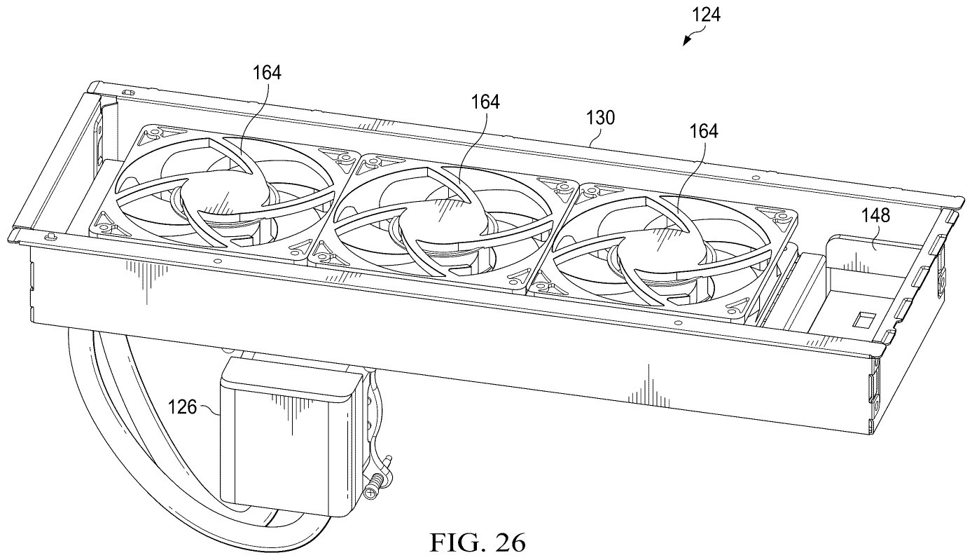

Referring now to FIG. 26, an upper perspective view depicts another example of the mounting frame 130 of a liquid cooling assembly 124 supporting a liquid cooling module 164 with only a portion of the mounting frame surface area used. In the example embodiment, a three fan liquid cooling module 164 with a length of 360 mm couples into mounting frame 130 with a single pump 126 and one blank 148 coupled in place to block airflow. In the example embodiment, the four blanks are sized to come out in order from left to right to accept a 240 mm, 280 mm, 360 mm and 420 mm liquid cooling module. In alternative embodiments, cooling fans may be used instead of liquid cooling modules.

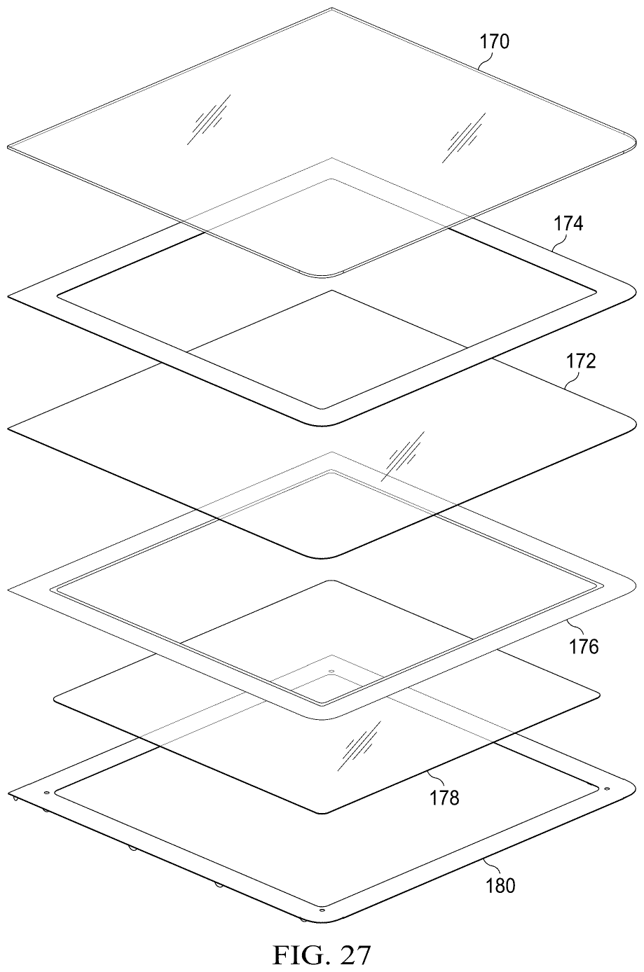

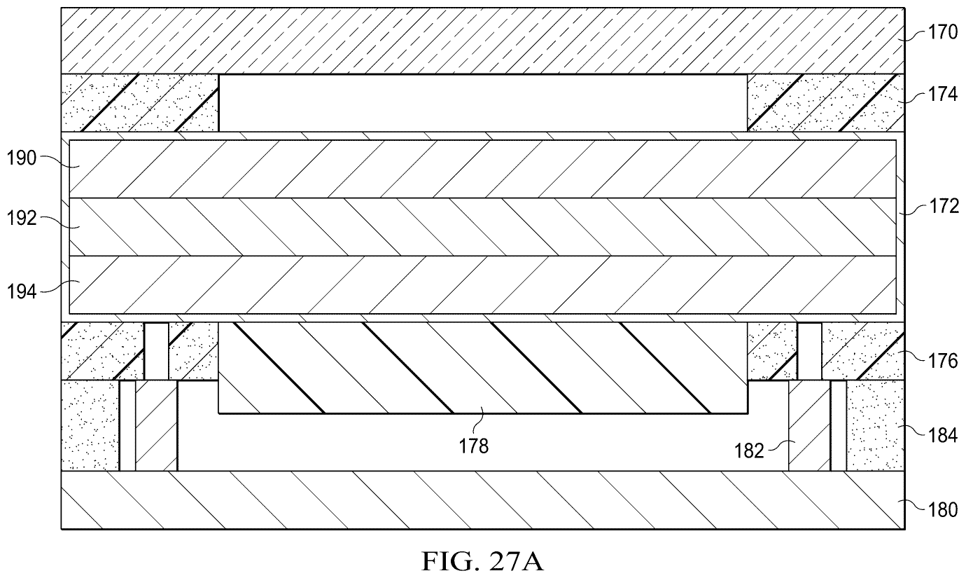

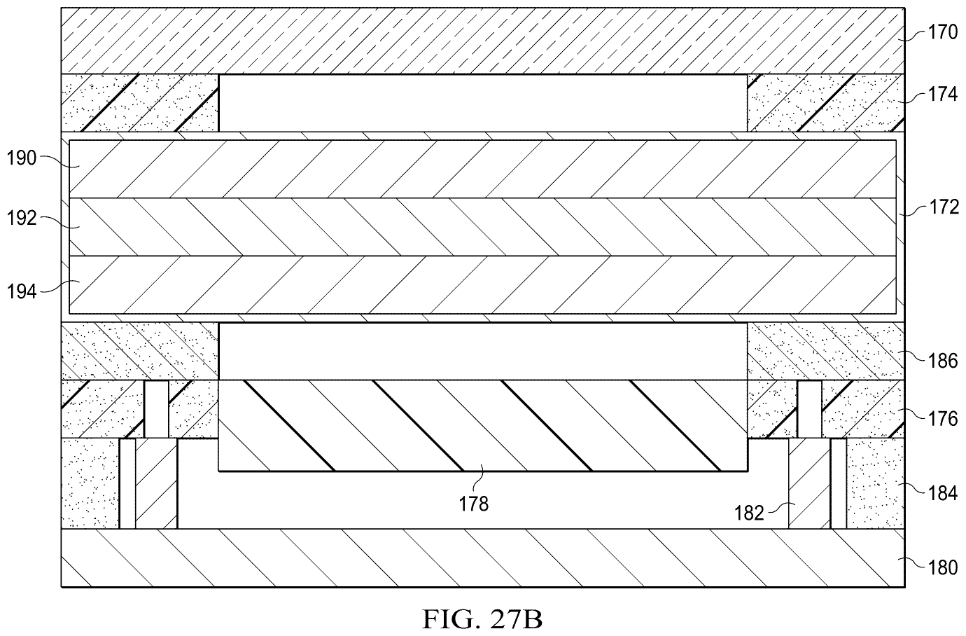

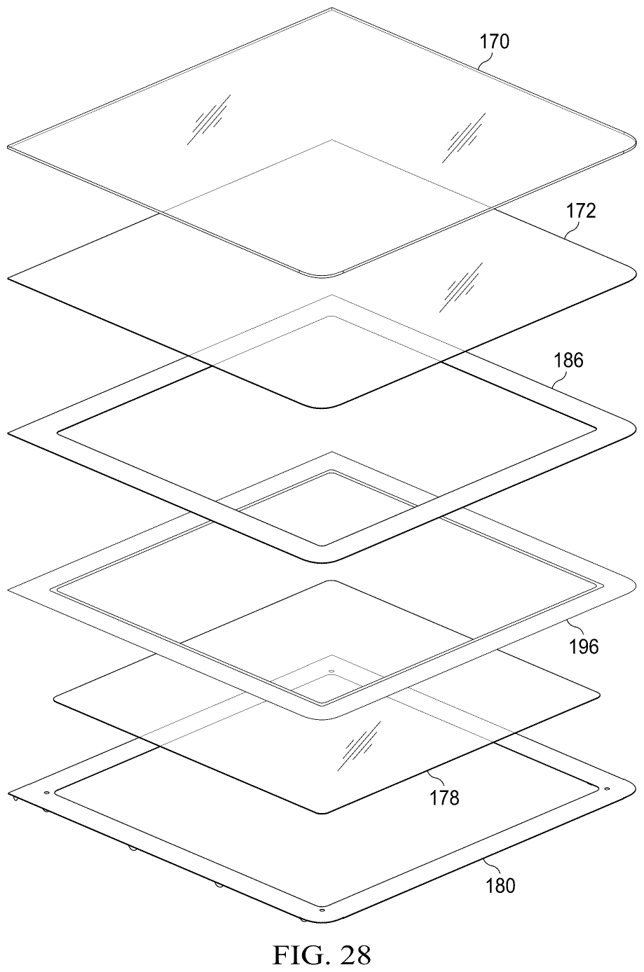

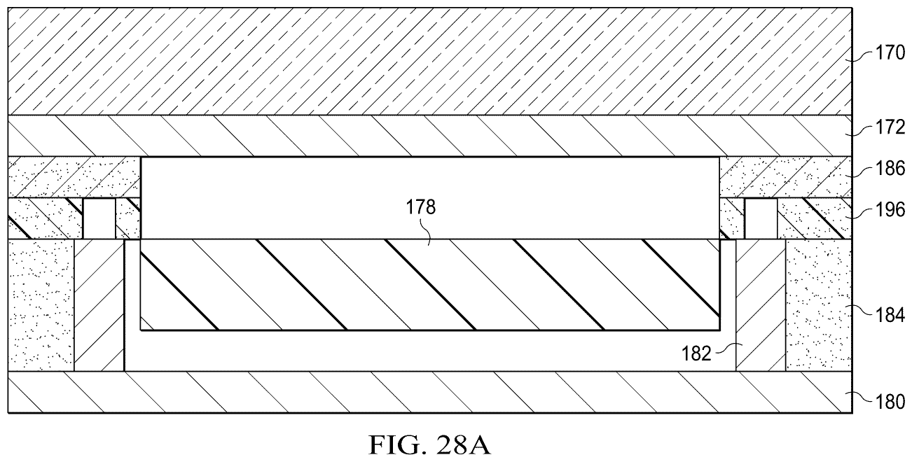

Referring now to FIGS. 27, 27A and 27B, example embodiments depict a transparent side cover assembly that provides viewing into a housing interior while preventing EMI from escaping the housing enclosure. In the example embodiment, indium tin oxide is coated on a clear substrate to provide EMI suppression with improved transparency. Silver is provided in a thin uniform coat and covered by indium tin oxide to optimize EMI suppression while reducing reflectivity. Silicon dioxide coated over the indium tin oxide seals the silver to reduce oxidation of the silver and maintain transparency over time. In the example embodiment of FIG. 27, a clear tempered glass 170 is electroplated in three separate sputter magnetron steps to form a conductive plating 172. Silver is plated first to a uniform coating of 13 to 15nm, followed by indium tin oxide to a uniform coating of 13 to 15 nm. Finally, a uniform coating of silicon dioxide is plated in a conductive form to seal the silver from oxidation. As shown in FIG. 27A, a black ink 174 treatment may be applied to the tempered glass at the perimeter before the metal deposition so that the perimeter of the transparent side cover is hidden where a metal frame 180 couples at the inner surface. On the silicon dioxide a split black ink layer 176 is painted or silk screened to further hide the inner metal frame coupling and offer an opening shown in FIG. 28A through which the silicon dioxide may interface with a ground to enhance EMI suppression. The magnetron sputtering of the silver layer 190, indium tin oxide layer 192 and silicon dioxide layer 194 are performed in separate steps using multiple targets at each step in the same machine to achieve thin uniform coats. Too thick of a silver layer will cause reflections while a thin layer of indium tin oxide controls conductivity and transparency. The silicon dioxide layer seals the silver to prevent a cloudiness that can happen when silver oxides.

In the example embodiment, an explosion proof film 178 is applied to the silicon dioxide so that any breakage of the clear substrate prevents shattering. An epoxy glue or other adhesive 184 is applied to the spilt black ink layer to couple the steel frame 180 in place and to capture a conductive gasket 182 shown in FIG. 27A. Conductive gasket 182 creates a conductive path through the opening of split black ink 176 between the silicon dioxide 194 and steel frame 180. FIG. 27B depicts an alternative treatment having a conductive black ink layer 186 that is applied between silicon dioxide layer 194 and split black ink layer 176 to help promote conductivity to the conductive layer 172. The conductive ink does not bond as well as nonconductive ink, so the split black ink layer improves application reliability.

Referring now to FIGS. 28 and 28A, an alternative embodiment is depicted for applying a conductive layer to the transparent substrate of the transparent side cover. In the example embodiment, conductive layer 172 is applied to the transparent substrate 170 of tempered glass without black ink. A conductive blank ink layer 186 is applied to the silicon dioxide with a low glue force of 4 to 15 micrometers. A split black ink layer 196 with an increased glue force of 4 to 15 micrometers is applied that leaves a gap through which conductive gasket 182 is able to establish a conductive interface. The explosion proof film 178 of 125 micrometers is applied and a bonding material 184 couples the split black ink and steel frame 180.

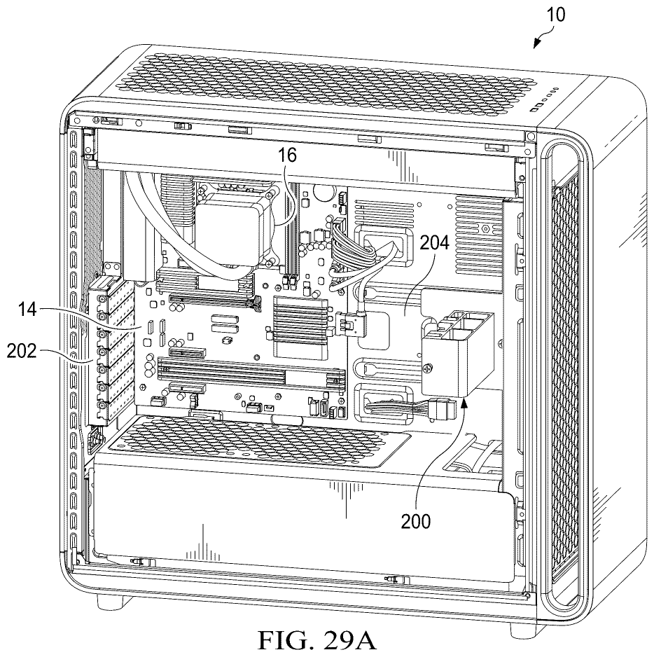

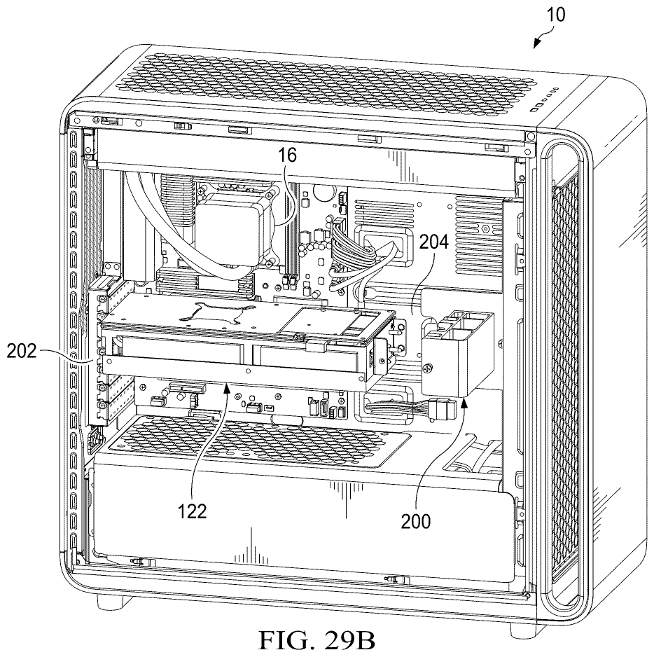

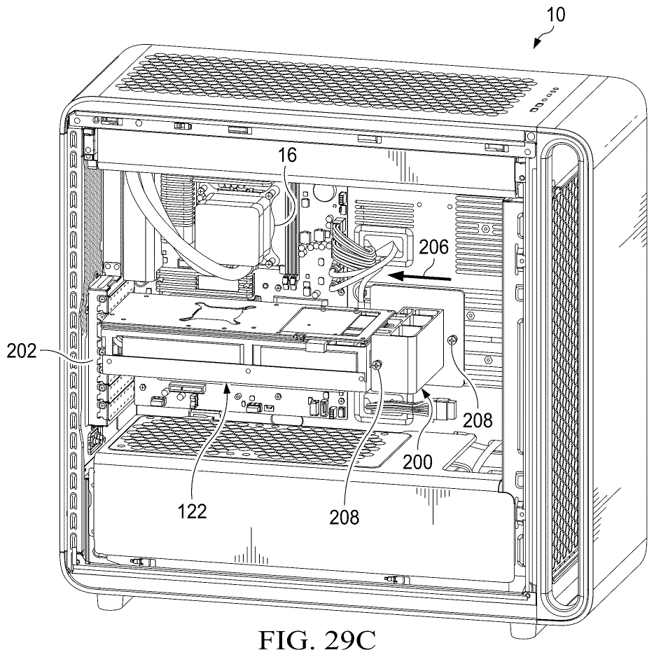

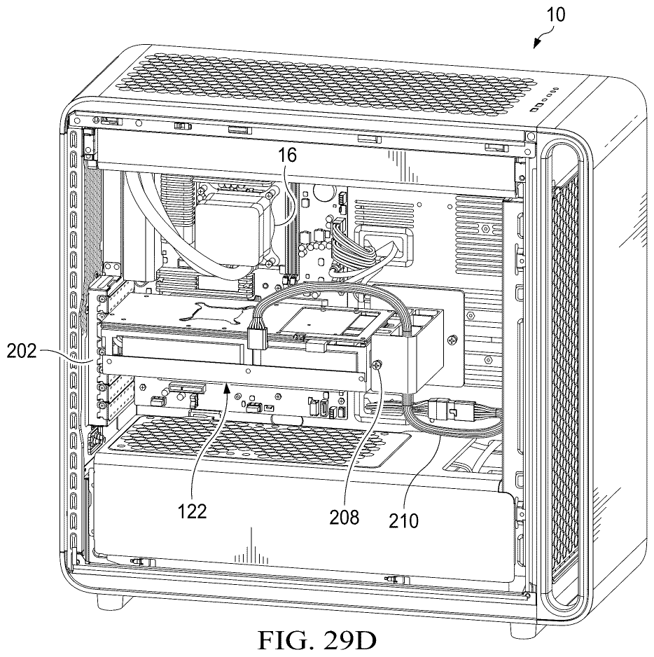

Referring now to FIGS. 29A, 29B, 29C and 29D, an example embodiment depicts coupling of a GPU card 122 into the information handling system housing with an add-in card (AIC) adapter 200. In the example embodiment, the GPU module couples into a PCIe slot coupled to a motherboard and interfaces with the motherboard by a cable, although alternative embodiments may couple the PCIe slots to a motherboard. FIG. 29A depicts information handling system 10 having a CPU 16 coupled to a motherboard 14 and interfaced with plural add-in card slots 202, such as PCI Express or M.2 slots. An add-in card adapter 200 is coupled to the housing interior chassis at a coupling assembly 204 to move laterally towards and away from add-in card slots 202. FIG. 29B depicts an add-in graphics card 122 inserted into add-in card slots 202 and having an add-in card coupling bracket coupled to the opposing end of the graphics card and aligned with the add-in card adapter 200. Add-in card adapter 200 is slid away from the add-in card slots to provide room for the graphics card insertion. FIG. 29C depicts the add-in card adapter 200 slid in the direction of arrow 206 towards the add-in card slots to couple against the GPU card 122 and hold the GPU card in place. Attachment screws 208 affix the add-in card adapter 200 in place on the chassis and to the add-in card to provide a secure physical connection. FIG. 29D depicts that a graphics cable 210 for the graphics card is routed through an opening of add-in card adapter 200, which provides organization for cable.

Add-in card adapter 200 supports a variety different graphics card lengths, widths, heights and weights in combination with add-in card brackets that cooperatively insert in vertical and horizontal slots of the add-in card adapter. The slots formed in the adapter in combination with the shape of the bracket that couples to the graphics card support securing mating features in vertical, horizontal and lateral directions. A mechanical lock, such as a thumb screw or bracket, secures the add-in card adapter to the chassis yet readily releases when an end user desires to change out the add-in card. In the example embodiment, the graphics card slots, graphics card and add-in card adapter adjust from the transparent side cover of the housing in an intuitive manner with all components visible to an end user before starting the add-in card modification.

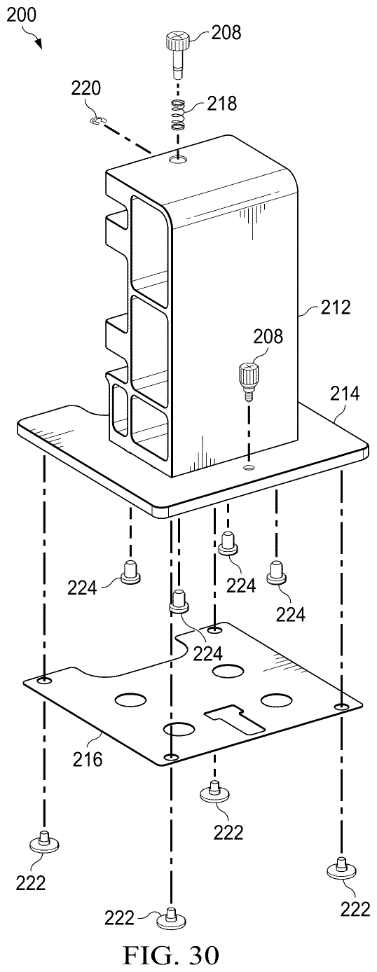

Referring now to FIG. 30, a side perspective exploded view depicts an example embodiment of the add-in card adapter assembly. In the example embodiment, an adapter body 212 couples to a base 214 having a mylar panel 216 bottom surface that reduces sliding friction. Four adapter screws 222 couple to a bottom surface of base 214 spaced to fit into slots formed in information handling system chassis. Four securing screws 224 couple body 212 to base 214. A captive screw 208 inserts into base 214 to couple to the chassis and lock the add-in card adapter in a position when assembled to the chassis. A thumb screw 208 assembled with a spring 218 and washer 220 inserts into body 212 to couple to an add-in card or add-in card bracket as shown above in FIG. 29C.

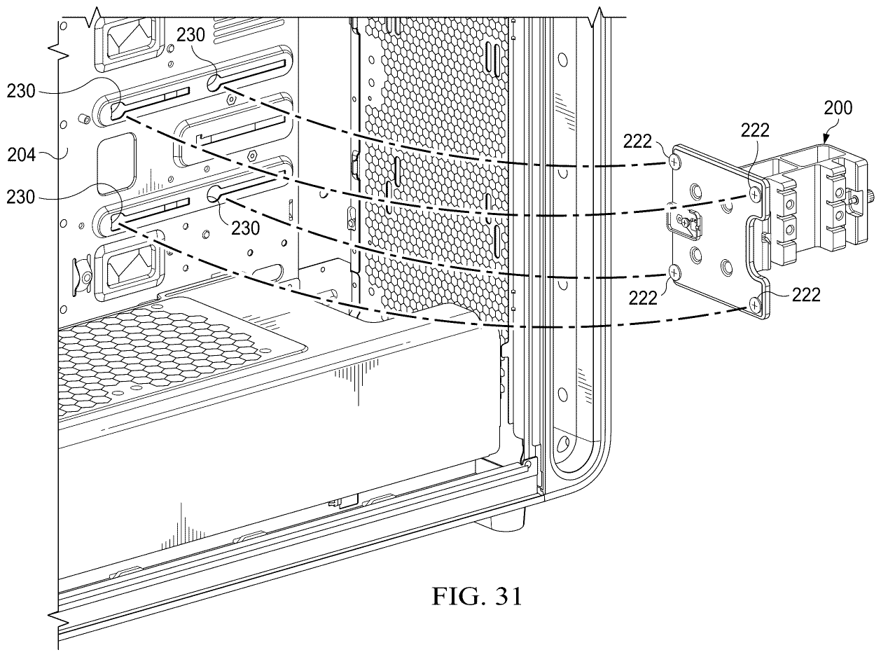

Referring now to FIG. 31, an add-in card adapter 200 is depicted aligned for insertion into slots 230 of a coupling assembly 204 of the system chassis. Each slot 230 has a larger dimension at one end in which to accept the head of screws 222 and then a small dimension along the length of the slot to hold the screw in the coupling assembly 204 of the chassis. Although the slots are referenced as horizontal and vertical slots with the add-in card adapter, the body of add-in card adapter 200 may couple in various orientations so that different apparent arrangements of vertical and horizontal slots of the body can couple to different types of brackets of the add-in card. For example, in an alternative embodiment the graphics card might have a vertical orientation instead the horizonal orientation shown.

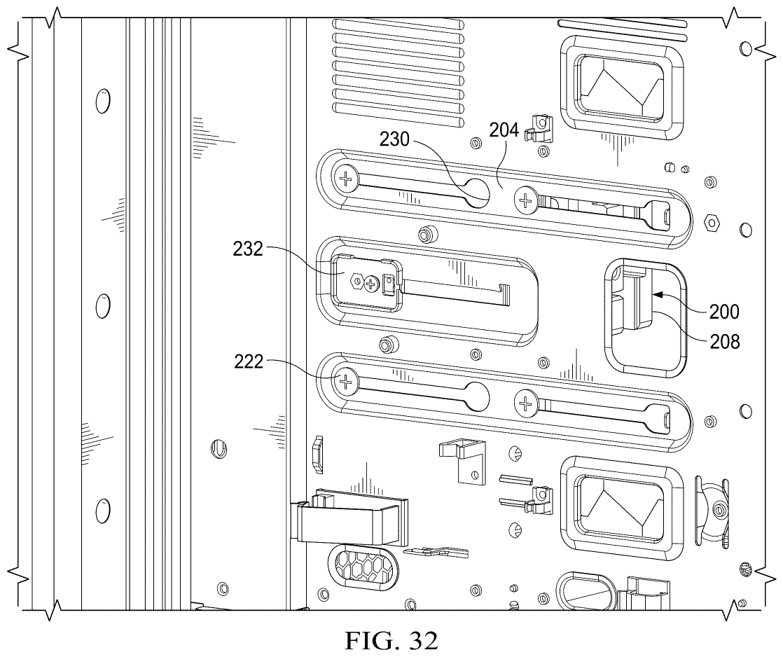

Referring now to FIG. 32, a rear view of the chassis at the coupling assembly is depicted having a locking bracket to hold the add-in card adapter in place when secured by the set screw. In the example embodiment, add-in card adapter couples with screws 222 through the slots and to a locking bracket 232 that slides at the rear side of the chassis opposite the add-in card adapter. When the captive screw 208 is tightened at locking bracket 232, the locking bracket tilts and twists at an integrated torsion spring that locks the bracket in place.

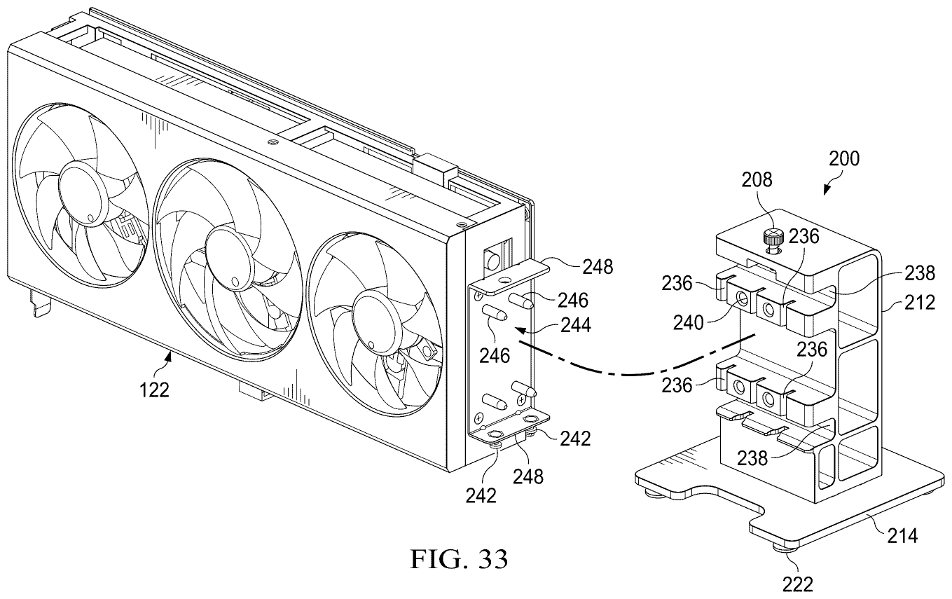

Referring now to FIG. 33, an example embodiment depicts coupling of a graphics card 122 by a C-shaped bracket 244 and insertion pins that fit into add-in card adapter 200. C-shaped bracket 244 couples with screws to graphics card 122 and has upper and lower horizontal walls 248 and four insertion pins 246. Add-in adapter 200 accepts the horizontal walls of C-shaped bracket 244 in horizontal slots 238 and accepts pins 246 in pin openings 240. A shoulder standoff 242 aligns the bracket to couple to the add-in adapter and set screw 208 engages in a threaded opening of C-shaped bracket 244.

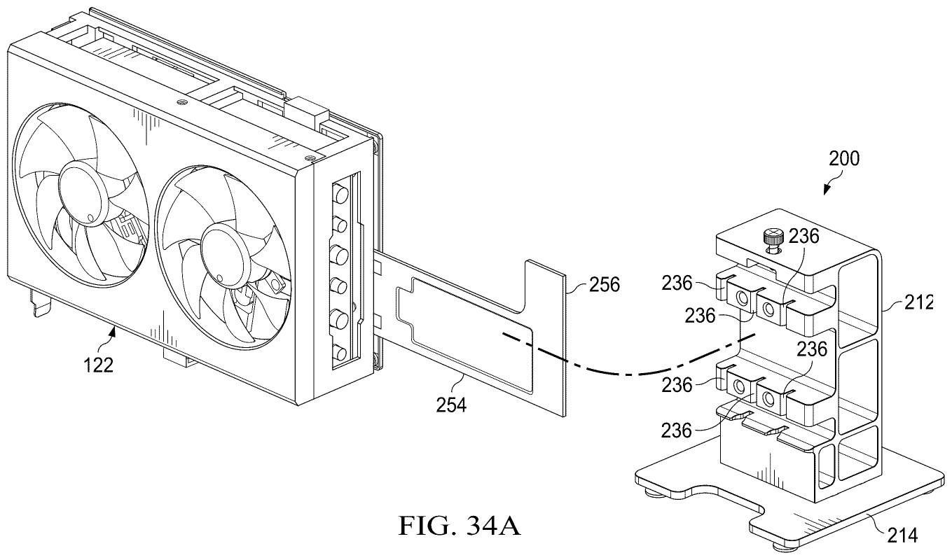

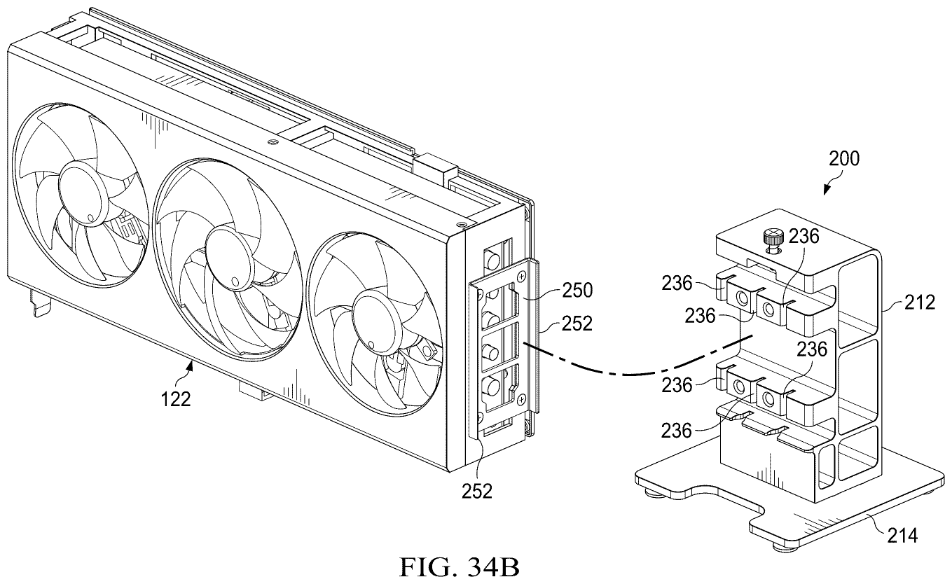

Referring now to FIGS. 34A and 34B, an example embodiment depicts coupling of a graphics card 122 by a U-shaped bracket 250 and a straight extender bracket 254. U-shaped bracket 250 of FIG. 34B has opposing vertical walls 252 that insert into vertical slots 236 of add-in adapter 200 and couples by screws to the graphics card. Straight extender bracket 254 of FIG. 34A has a single edge 256 that fits into a single vertical slot 236. Adjustments to the coupling relationship may be provided by changes to the size of the walls of the C-shaped and U-shaped brackets in addition to changes in the sliding position of the add-in card adapter so that a wide variety of graphic card heights, widths and lengths may be supported.

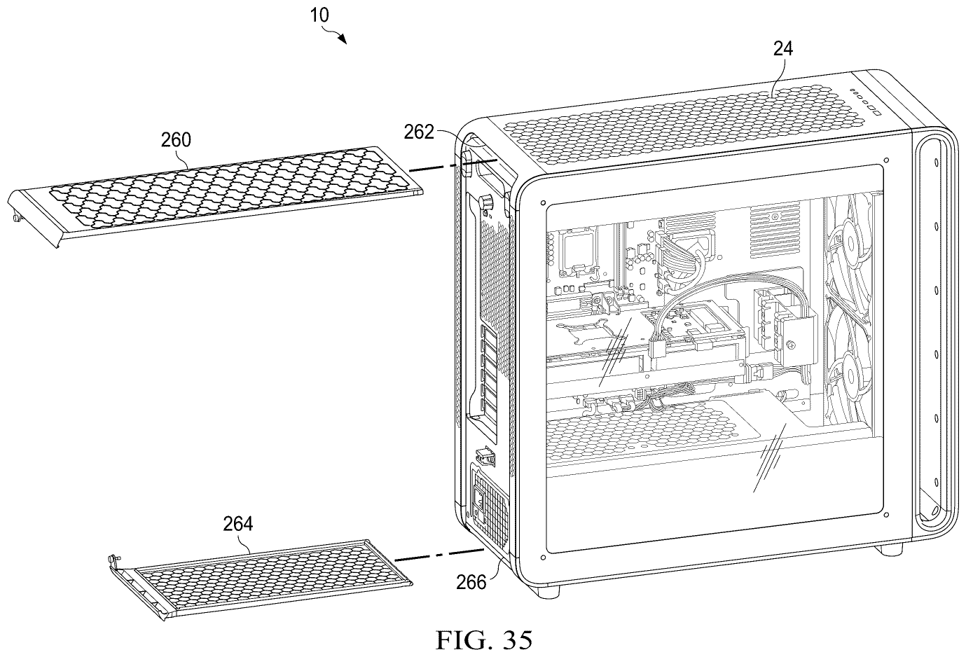

Referring now to FIG. 35, a rear side perspective view depicts air filters that slide into air filter slots of the information handling system 10. In the example embodiment, a top filter slot 262 accepts insertion of a top filter 260 that filters air flowing through housing top cover 24, such as air pulled into or exhausted from the liquid cooling modules described above. A bottom filter slot 266 accepts a bottom air filter 264 that filters are pulled into or exhausted from the bottom housing cover. Each air filter inserts and removes at its respective slot with the housing in a locked configuration by having a handle exposed at the end of the air filter. In one alternative embodiment, an additional air filter may fit under the system front cover. Each air filter is removable and cleanable with a wide area of substantially the housing side dimensions to ensure adequate airflow through defined regions, such as the liquid cooling modules as described above. EMI suppression is provided by a grounded conductive frame holding a conductive wire mesh with an open area of greater than 60%. The conductive frame has EMI contacts to ground to the system housing and a safety screw to meet safety regulations such as IEC 62368 and UL 60950, such as by remaining attached to the air filter when unscrewed from the housing. When installed in the housing slot, the air filters complete a Faraday cage and fire enclosure. For example, the conductive frame is an overmolded plastic onto the wire mesh or attached by mechanical devices like adhesives or heat stakes. An EMI conductive gasket attaches to the wire mesh to contact the system housing, such as the interior chassis, when the filter is installed thereby grounding the wire mesh. The integrated structure completes a fire enclosure by defining air vents within safety constraints of IEC 62368 and UL 60950 that has the wire mesh securing filter material to prevent it from falling into the chassis interior. In the example embodiment, the top air filter 260 inserts between an open vented top cover 24 and a frame of the liquid cooling assembly to have an airtight seal defined at a substantially similar perimeter size of the air filter, chassis and liquid cooling assembly frame.

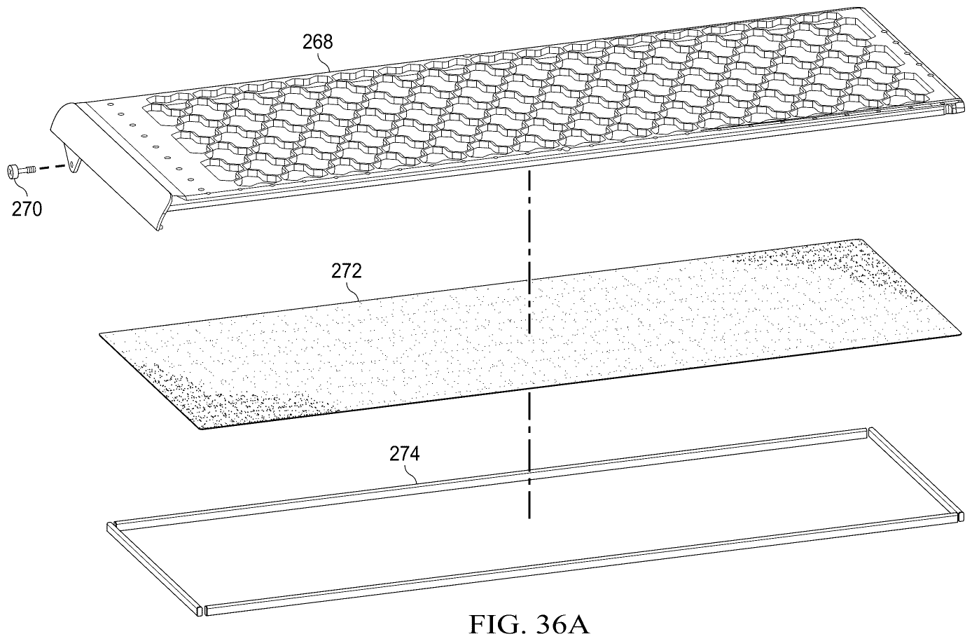

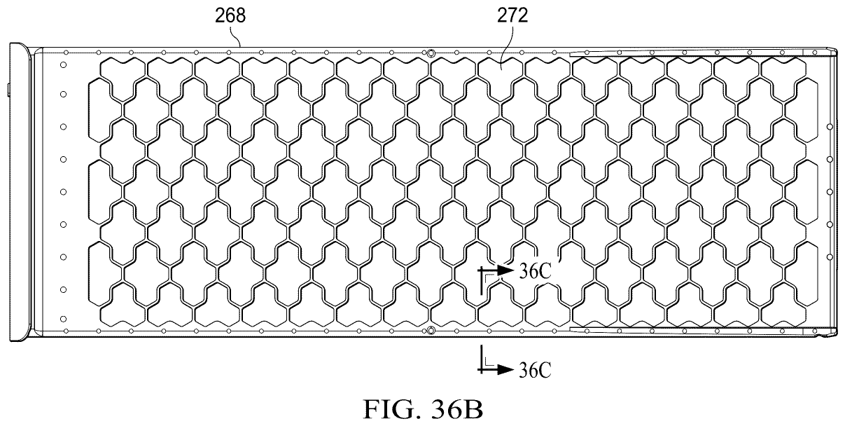

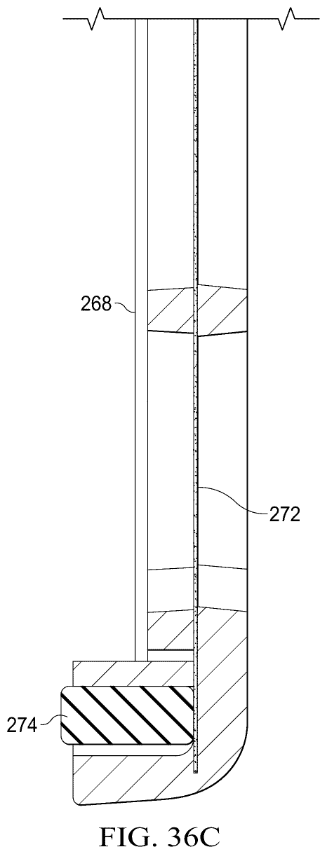

Referring now to FIGS. 36A, 36B and 36C, an example embodiment of the top filter 260 illustrates the integrated EMI design. FIG. 36A depicts an exploded view of the top air filter having a frame 268 of a conductive material, such as steel or aluminum, a conductive mesh 272 that filters air and suppresses EMI and an EMI conductive gasket 274 that couples to the conductive frame and conductive mesh to ground with the system housing. In one embodiment, frame 268 is injection molded plastic that is overmolded onto conductive mesh 272 and EMI gasket 274. A captive security screw 270 fastens the filter to the housing to prevent inadvertent removal and to offer an additional ground interface to the housing. FIG. 36B depicts a top view of the top filter and indicating a sectional view shown in detail by FIG. 36C. The plastic frame has spaced openings to pass air to the conductive mesh, which filters the air. Frame 268 captures conductive mesh 272 with a pattern of openings that supports the mesh from distorting under the pressure of airflow drawn through the filter. Conductive mesh 272 is captured in a central portion of frame 268 by overmolding to securely hold the mesh in position. The EMI gasket 274 is a conductive material that seals against the system housing chassis and liquid cooling assembly frame and establishes a conductive interface with the system ground. EMI gasket 274 is overmolded to contact against conductive mesh 272 so that the air filter has a grounded conductive surface across the air opening that prevents EMI transfer out of the housing. In one embodiment, the EMI suppression provides 5 dB of EMI margin below 1 GHz and 2.6 dB of margin above 1 GHz. In alternative embodiments, a more fine mesh may be used to further suppress EMI in higher frequencies.

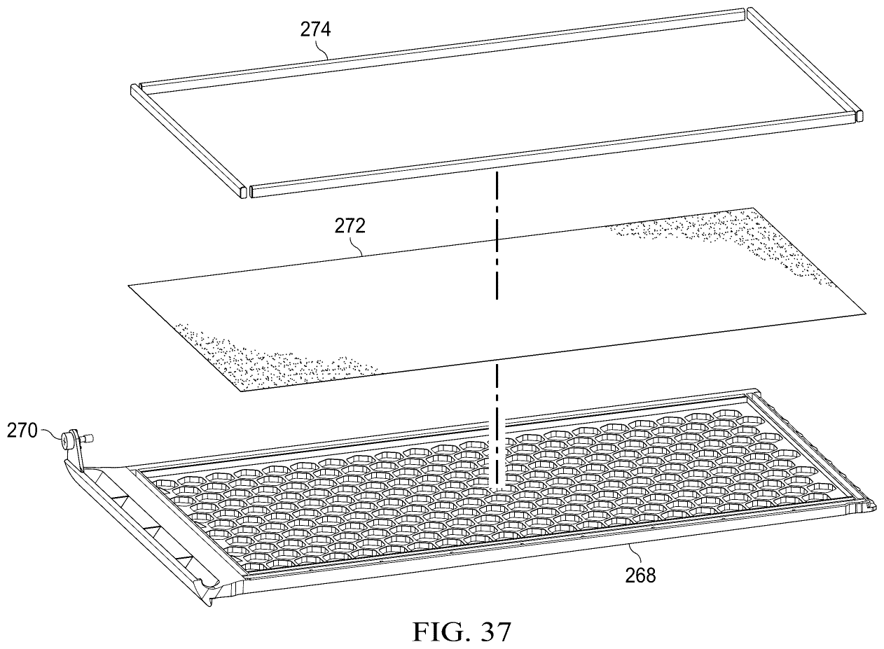

Referring now to FIG. 37, an exploded perspective view of the bottom filter depicts a construction similar to the top filter. For example, a plastic frame 268 is overmolded to enclose conductive mesh 272 in contact with a conductive EMI filter 274. In addition to EMI suppression, the air filters when installed help to suppress acoustics relative to conventional air filters since the wire-to-frame open area is comparable to a chassis open area, such as 60% coverage.

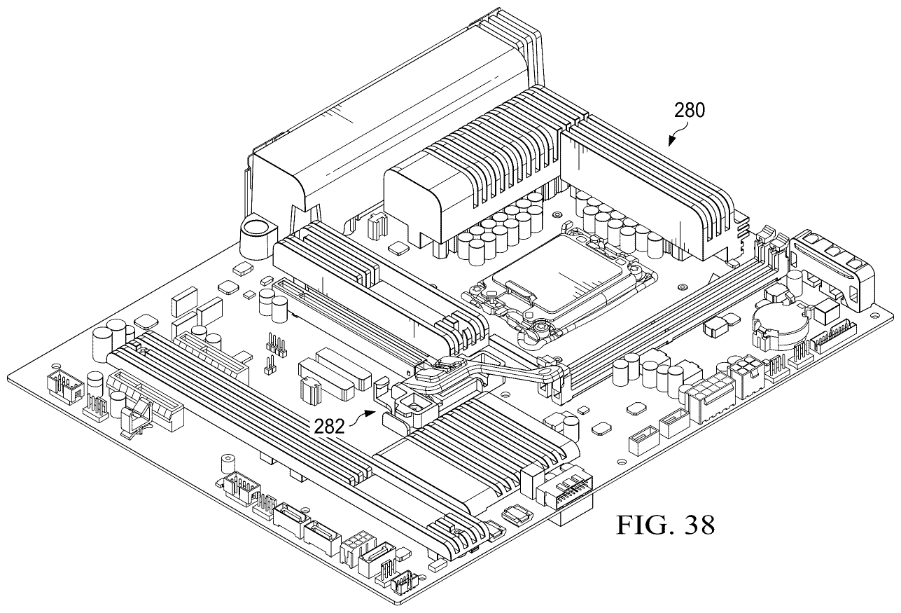

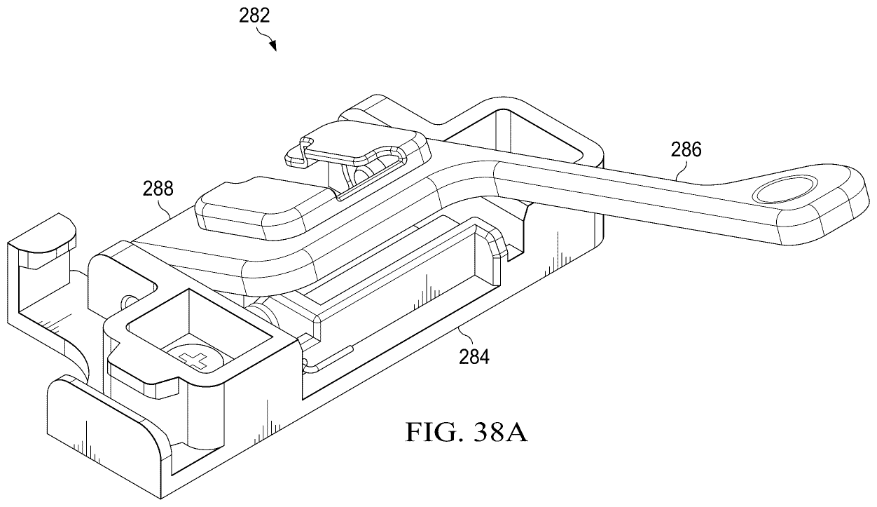

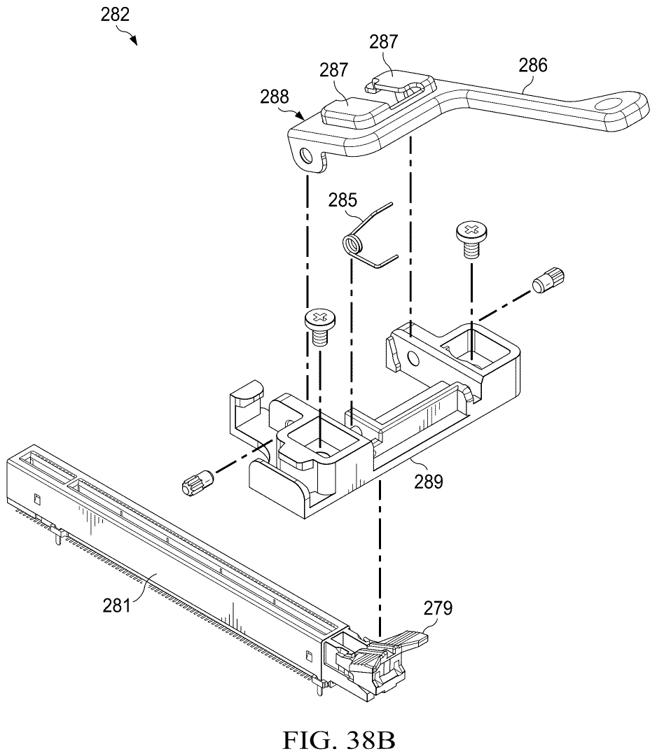

Referring now to FIGS. 38, 38A and 38B, an example embodiment depicts a PCIe slot latch release 282 to assist removal of a graphics card coupled to a circuit board 280. In the example embodiment, latch release 282 couples to circuit board 280 at the PCIe slot with an arm on either side of the PCIe slot so that a press on the latch release provides a uniform lifting force to the graphics card for removal from the slot. FIG. 38A depicts latch release 282 separate from the circuit board. In the example embodiment, a base 284 couples to the circuit board and is built of a plastic resin that can be unfilled or filled with additives such as talc, minerals, glass fiber, carbon fiber, etc., so that the mechanical properties are adjusted to an anticipated lifting force that can vary based upon graphics card size. In one embodiment, base 284 couples to the circuit board as a separate and independent unit with a modular design that couples a latch extender 288 with a subsequent assembly. Alternatively, latch release 282 may mount as an assembled unit to the circuit board. A latch extender 288 has a Y-shape with arm members that fit around an inserted graphics card and the PCIe slot. A torsion spring included in the base engages with the latch extender to rotate a release arm 286 to a raised position. The latch extender 288 and arm 286 are metal, such as a stamped or die cast piece, that accepts force of a press down at arm 286 to rotate latch extender 288 at base 284 and generate a lifting motion to a graphics card installed in the graphics card slot. Alternatively, latch extender 288 may use other structural materials, such as structural engineered plastics.

FIG. 38B depicts an exploded perspective view of the PCIe latch release that couples with a base member 289 to a circuit board at a PCIe slot 281. Base member 289 rotationally couples latch extender 288 so that arms 287 extend under the add-in card and bias to a lowered position with a spring 285. Latch extender 288 aligns with a latch button 279 so that when arm 286 is pressed down latch button 279 is activated to release the add-in card and arm members 287 can press upward to lift the add-in card out of the PCIe slot 281.

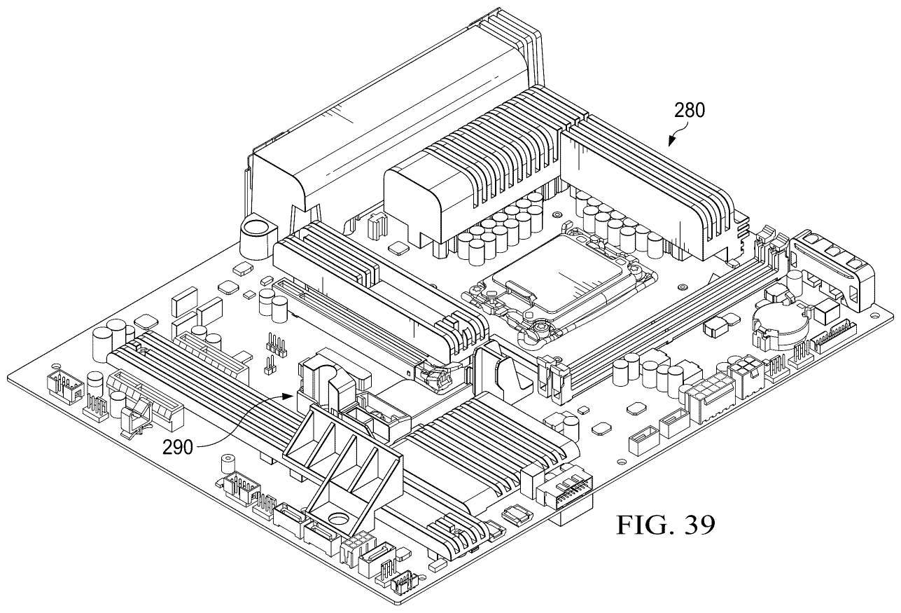

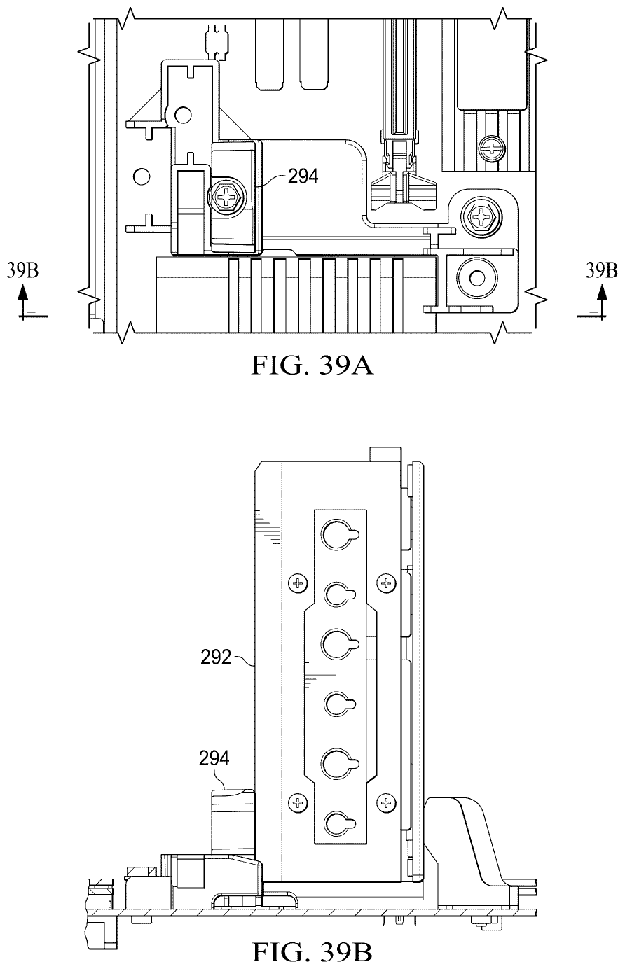

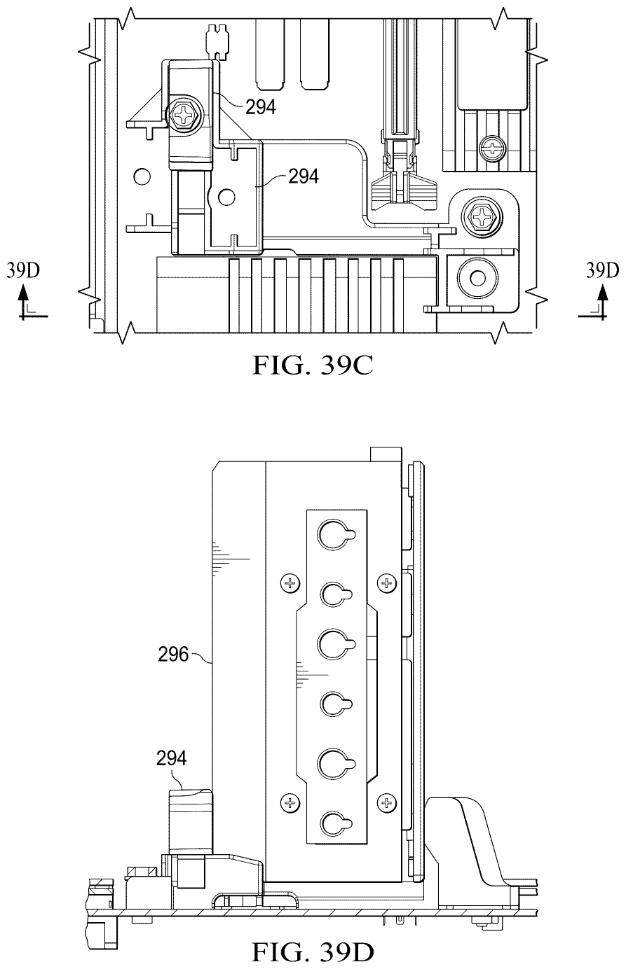

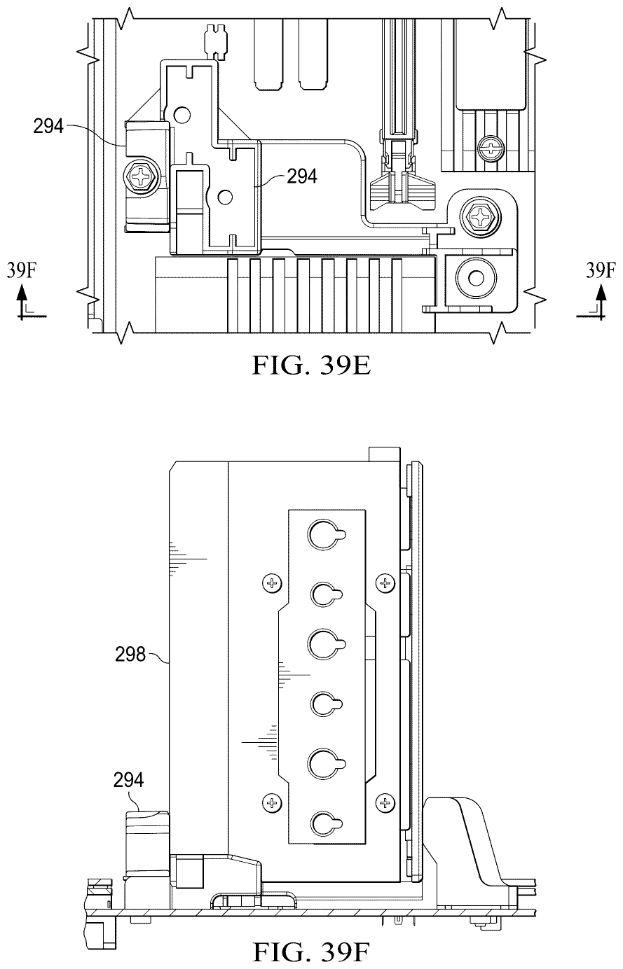

Referring now to FIGS. 39, 39A, 39B, 39C, 39D, 39E and 39F, an example embodiment depicts a graphics card bottom support 290 to aid in retention of a graphics card at a circuit board 280. The graphics card bottom support 290 works in conjunction with latch release 282 so that the forces placed against a circuit board and PCIe slot do not damage the system when a graphics card is inserted, held in place and removed. Bottom support 290 couples to circuit board 280 at different positions based upon the size of the graphics card that is inserted in the PCIe slot. At each position and for each graphics card, the bottom support extends outward from the circuit board to create a ledge that fits under the graphics card and accepts the weight of the graphics card for distribution across a wider area, particularly during shipment of the information handling system. FIGS. 39A and 39B depict a 2W graphics card 292 inserted into the PCIe card having a position for a bottom support member 294 moved towards the PCIe slot to meet against the bottom side of the graphics card. FIGS. 39C and 39D depict a 2.5W graphics card 296 with bottom support member 294 slid away from the PCIe slot to a middle location where it meets against the bottom side of the graphics card. FIGS. 39E and 39F depict a 3W graphics card 298 coupled in the PCIe slot with the bottom support member slid to a distal location so that the bottom support member rests against a bottom side of the graphics card. Different sizes of graphics cards and other types of devices that fit into the circuit board slot may be supported as desired. When PCIe slot latch release 282 is also placed under the PCIe card, the base helps to accept some of the weight and distribute that weight across the circuit board.

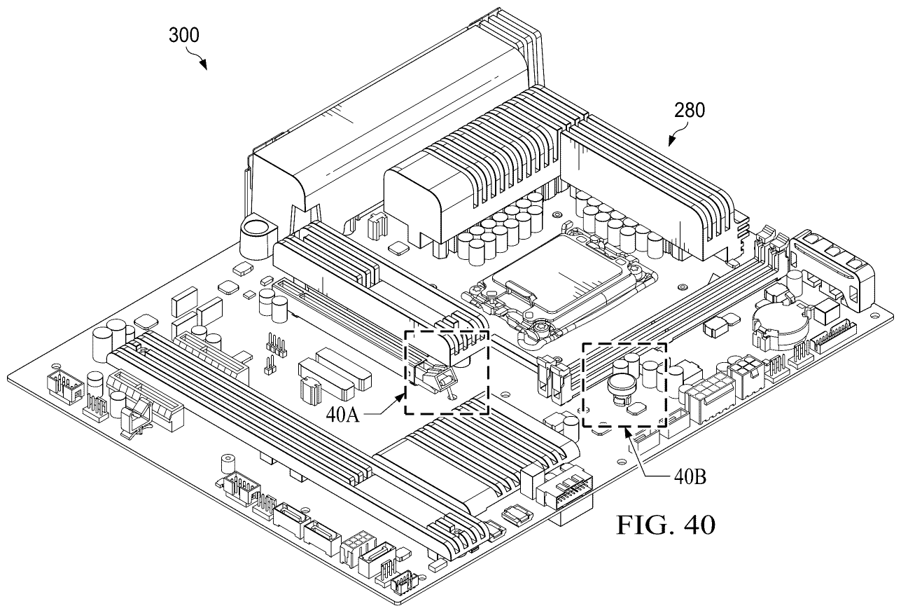

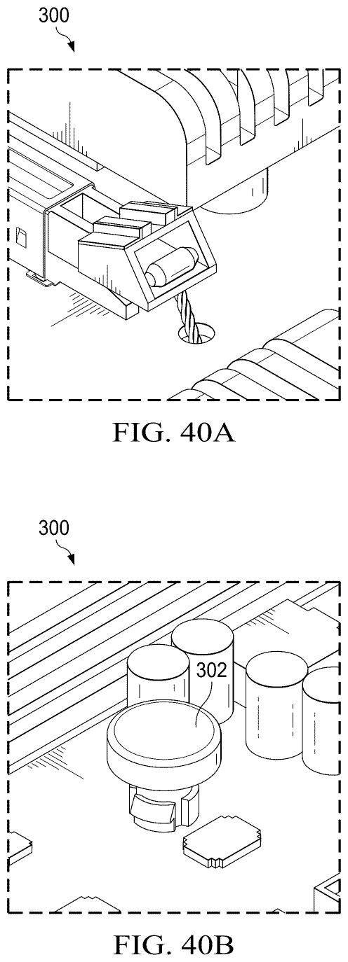

Referring now to FIGS. 40, 40A and 40B, an alternative example of a PCIe slot latch release 300 depicts a release button 302 accessible at the circuit board 280 that accepts a press to activate a graphics card latch release and remove an add-in card out of the PCIe slot. In the example embodiment, latch release 300 is activated when push button 302 is pressed and the force of the press is transferred by a wire and pulley at a bottom side of circuit board 280. FIG. 40 depicts that latch release 300 shown in detail by FIG. 40A has a minimal footprint in the proximity of the PCIe slot while release button 302 is displaced laterally to a clear location of circuit board 280 as shown in detail by FIG. 40B. Displacement of the release button from the latch release offers great flexibility in motherboard placement of the PCIe slots.

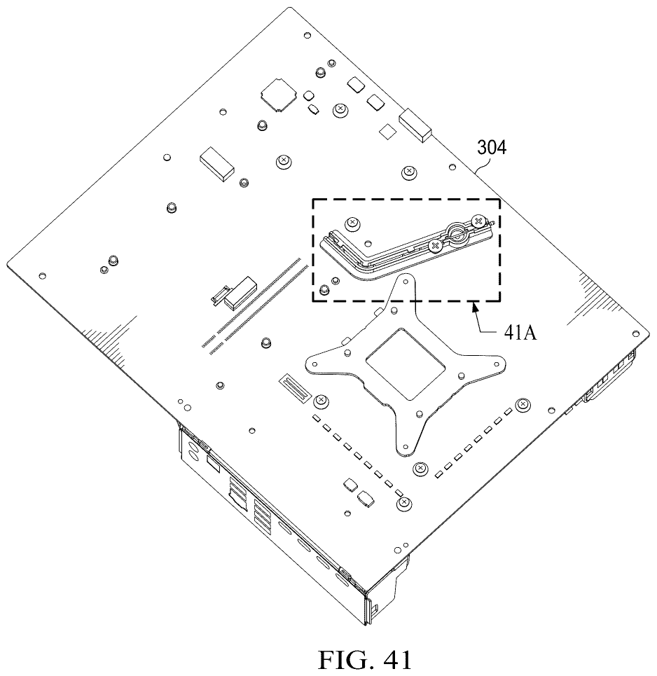

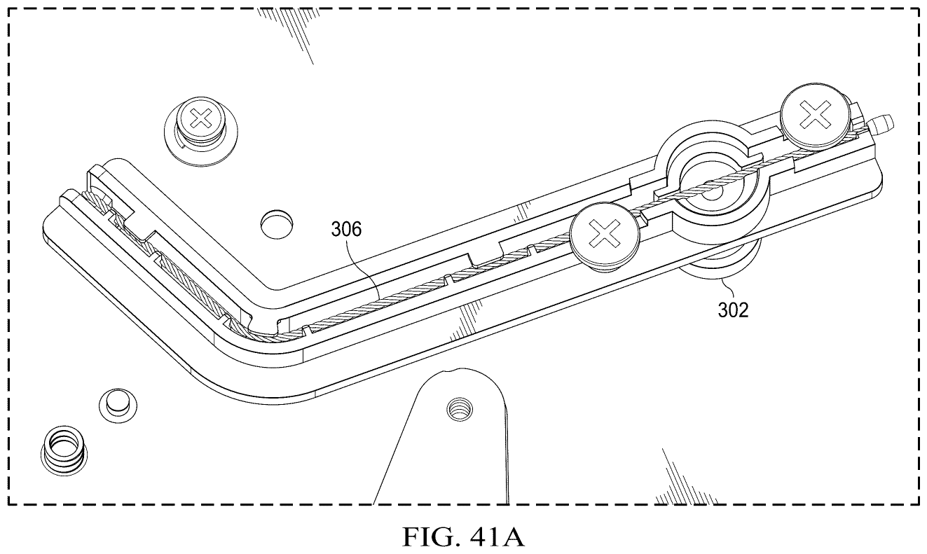

Referring now to FIGS. 41 and 41A, a bottom view depicts the alternative example of the PCIe latch release having a wire 306 that transfers release actuation. Pressing on button 302 places a force on wire 306 that presses the wire downward and away from the bottom surface of the circuit board. The downward movement of the wire pulls the wire from the location of the latch release so that the force of the press is transferred through the pulley of the latch release to a downward movement of the latch release against the base of the graphics card PCIe slot.

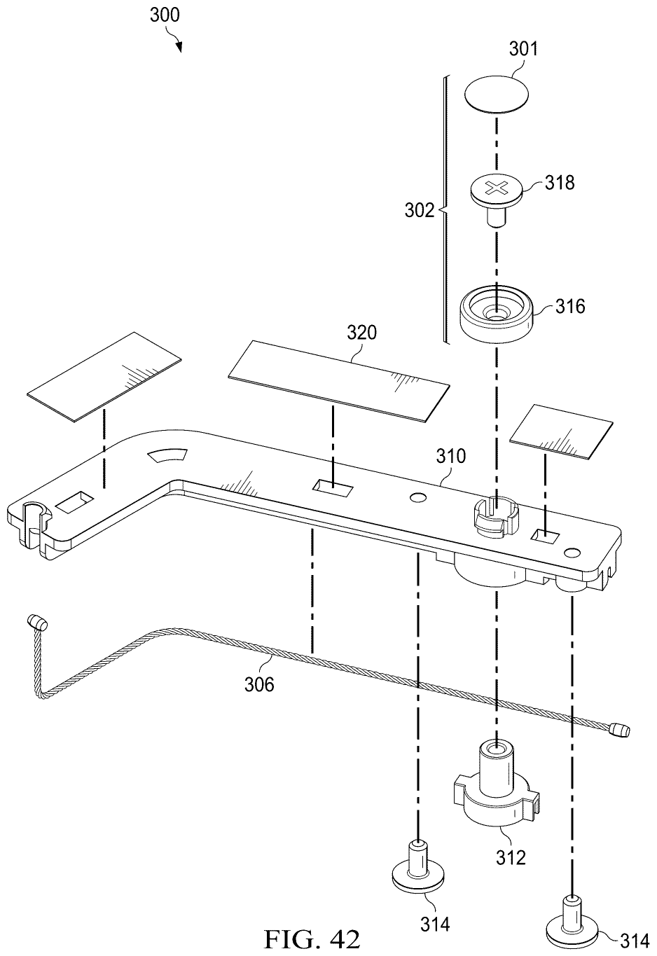

Referring now to FIG. 42, an exploded perspective view depicts the alternative example of the PCIe latch release 300. A guide 310 couples to a bottom side of the circuit board and defines a transfer vector that the wire applies to transfer a button press into release movement against the graphics card. An adhesive 320 couples guide 310 to the circuit board. Wire 306 is captured in guide 310 with stops at each end to limit movement of the wire relative to the guide. A press actuator 312 is captured between the wire and guide with securing devices 314 so that press on press actuator 312 will press wire 306 downwards and out of guide 310. Button 302 has a button top 301 that couples to a button guide 316 that holds a button member 318 engaged with press actuator 312 through an opening of guide 310. The stop at the far end of guide 310 extends out of the top side of guide 310 to couple with a pulley that transfers a downward force into an actuation force to release the graphics card out of the PCIe slot.

Although the present invention has been described in detail, it should be understood that various changes, substitutions and alterations can be made hereto without departing from the spirit and scope of the invention as defined by the appended claims.

What is claimed is:

1. An information handling system comprising:
a housing having a first air filter slot proximate a removeable top cover;
a processor coupled in the housing and operable to execute instructions that process information;
a memory interfaced with the processor and operable to store the instructions and information; and
a first air filter sized to slide into the first air filter slot and having a conductive wire mesh integrated in a frame that fills an opening between the removeable top cover and an interior of the housing, the conductive wire mesh interfaced with a ground of the housing.

2. The information system of claim 1 further comprising:
a conductive gasket coupled at a perimeter of the first air filter frame to seal the opening between the removeable top and the housing interior;
wherein the frame comprises plastic molded over the conductive wire mesh.

3. The information handling system of claim 2 further comprising:
a liquid cooling assembly coupled in the opening between the removeable top and the interior of the housing;
wherein air flows between the housing interior and openings in the removeable top cover through the conductive wire mesh and liquid cooling assembly sealed by the conductive gasket.

4. The information handling system of claim 3 further comprising:
a removeable bottom cover, the housing having a second air filter slot proximate the removeable bottom cover; and
a second air filter sized to slide into the second air filter slot, the second air filter having a conductive mesh integrated in a frame that fills an opening between the removeable bottom cover and the interior of the housing.

5. The information handling system of claim 4 further comprising:
a conductive gasket coupled at a perimeter of the second air filter frame to seal the opening between the removeable bottom cover and the housing interior;
wherein the frame comprises plastic molded over the conductive wire mesh.

6. The information handling system of claim 5 wherein the locking mechanism further comprises:
a first tooled fastener inserted through a first screw opening of the first air filter to couple with the housing and secure the first air filter; and
a second tooled fastener inserted through a second screw opening of the second air filter to couple with the housing and secure the second air filter.

7. The information handling system of claim 6 further comprising:
a first handle formed in the first air filter frame and exposed at the housing rear side; and
a second handle formed in the second air filter frame and exposed at the housing rear side.

8. The information handling system of claim 5 wherein the first and second air filter dimensions are substantially the dimensions of the opening at the housing top cover and bottom cover.

9. The information handling system of claim 8 wherein air flow to cool the processor passes between the first and second air filters.

10. A method for cooling information handling system housing interior, the method comprising:
overmolding a conductive wire mesh in a plastic frame;
inserting the plastic frame into a slot of the housing to fill an opening between the housing interior and exterior;
interfacing the conductive wire mesh with the housing to ground the conductive wire mesh; and
passing cooling airflow between the housing interior and exterior through the conductive wire mesh.

11. The method of claim 10 further comprising:
coupling a conductive gasket to a perimeter of the air filter interfaced with the conductive mesh;
sealing the airflow at a perimeter of the housing opening with the conductive gasket; and
grounding the conductive mesh to the housing through the conductive gasket.

12. The method of claim 10 further comprising:
coupling a liquid cooling assembly frame in the housing opening;
coupling a conductive gasket to a perimeter of the air filter interfaced with the conductive mesh;
sealing the airflow at a perimeter of the liquid cooling assembly frame with the conductive gasket; and
grounding the conductive mesh to the housing through the liquid cooling assembly frame and the conductive gasket.

13. The method of claim 12 further comprising:
removing some but not all blanks of the liquid cooling assembly frame to define an opening in the liquid cooling module frame;
coupling a liquid cooling module in the liquid cooling assembly frame opening; and
blocking airflow between the housing interior and exterior with the blanks that remain in the liquid cooling assembly frame.

14. The method of claim 13 further comprising:
coupling a safety fastener to air filter frame; and
coupling the air filter to the housing with the safety fastener.

15. The method of claim 14 further comprising coupling a bottom air filter in the housing bottom to flow air between the housing interior and exterior through both the air filter and the bottom air filter.

16. An information handling system comprising:
a housing having a first air filter slot and an opening to flow air between an interior and an exterior of the housing;
a first air filter sized to fit in the first air filter slot and having a conductive wire mesh integrated with a plastic frame; and
a conductive gasket coupled to a perimeter of the first air filter and interfaced with the conductive wire mesh and the housing to ground the conductive wire mesh, the conductive gasket sealing off air flow between the perimeter of the first air filter and the housing.

17. The information handling system of claim 16 further comprising:
a liquid cooling assembly having a frame holding a liquid cooling module, the frame coupled to the housing at the opening;
wherein the conductive gasket seals at the liquid cooling assembly frame.

18. The information handling system of claim 17 wherein the liquid cooling assembly, the housing opening and the liquid cooling module assembly frame have substantially the same dimensions to direct air flow between the housing interior and exterior through the first air filter and the liquid cooling assembly.

19. The information handling system of claim 18 wherein:
the first air filter slot is located at a rear side of the housing proximate a top cover of the housing; and
a second air filter slot is located at a rear side of the housing proximate a bottom cover of the housing.

20. The information handling system of claim 19 further comprising a second air filter having conductive wire mesh integrated in a plastic frame and a conductive gasket interfacing the conductive wire mesh and the ground of the housing.
